(19) United States
(12) Patent Application Publication
(10) Pub. No.: US 2026/0247710 A1
(43) Pub. Date: Aug. 20, 2026

(54) THIN FILM TRANSISTOR, DISPLAY SUBSTRATE, METHOD FOR MANUFACTURING THE DISPLAY SUBSTRATE AND DISPLAY DEVICE

(71) Applicants: Nanjing BOE Display Technology CO.,LTD., Nanjing, Jiangsu (CN); BOE TECHNOLOGY GROUP CO., LTD., Beijing (CN)

(72) Inventors: Baoze FU, Beijing (CN); Zhilei SUN, Beijing (CN); Haijiao QIAN, Beijing (CN)

(21) Appl. No.: 18/995,231

(22) PCT Filed: Apr. 17, 2024
(86) PCT No.: PCT/CN2024/088173

§ 371 Date: Jan. 16, 2025

(30) Foreign Application Priority Data
May 31, 2023 (CN) 202310637897.8

(51) Int. Cl. H10D 86/40; H10D 86/01

(52) U.S. Cl. CPC H10D 86/423; H10D 86/0221; H10D 86/441

(57) ABSTRACT

A thin film transistor, a display substrate, a method for manufacturing the display substrate, and a display device are provided, the thin film transistor includes: a gate and an active layer. The active layer includes: a first conductive portion, a second conductive portion, and a channel portion connected between the first conductive portion and the second conductive portion, wherein the channel portion is opposite to the gate and insulated from the gate, a material of the active layer includes a metal oxide MxNyOz, M and N respectively includes any one or more of zinc, indium, gallium, tin, and lanthanide metals, O is an oxygen element, x, y, and z representing an molar ratio or mass fraction of M, N, O elements in the entire metal oxide, respectively, x, y, and z each being greater than 0, and 0.8≤x+y+z≤1.0.

### TECHNICAL FIELD

The present disclosure relates to the field of display technology, and in particular to a thin film transistor, a display substrate, a method for manufacturing the display substrate and a display device.

### BACKGROUND

With the development of information and networks, electronic display technology has become a widely used technology. At present, LCD (liquid Crystal display) display devices and AMOLED (Active Matrix/Organic Light Emitting Diode) display devices are widely used. In general, the LCD display devices and the AMOLED display devices are driven by adopting the active matrix driving technology, such as a driving method of the TFT (thin Film transistor) array substrate.

### SUMMARY

The present disclosure provides a thin film transistor, a display substrate, a method for manufacturing the display substrate and a display device.

The present disclosure provides a thin film transistor including a gate and an active layer disposed on a base substrate, the active layer including: a first conductive portion, a second conductive portion, and a channel portion connected between the first conductive portion and the second conductive portion, where the channel portion is opposite to the gate and insulated from the gate, a material of the active layer includes a metal oxide MxNyOz, M and N respectively includes any one or more of zinc, indium, gallium, tin, and lanthanide metals, O is an oxygen element, x, y, and z each are natural numbers greater than 0, and 0.8≤x+y+z≤1.0.

In some implementations, the active layer is of a single-layer structure and includes at least zinc, indium, gallium, tin and oxygen elements, a molar ratio of the indium element to the gallium element ranging from 3.6:1.2 to 4.0:1.2, a molar ratio of the gallium element to the zinc element ranging from 1:4 to 1.4:4, and a molar ratio of the zinc element to the tin element ranging from 3.8:1 to 4.2:1.

In some implementations, the active layer includes a first sub-layer and a second sub-layer stacked in sequence, the first sub-layer is closer to the gate than the second sub-layer, and the second sub-layer has a hall mobility greater than that of the first sub-layer; the second sub-layer includes at least zinc, indium, gallium, tin and oxygen elements, a molar ratio of the indium element to the gallium element ranges from 3.6:1.2 to 4.0:1.2, a molar ratio of the gallium element to the zinc element ranges from 1:4 to 1.4:4, and a molar ratio of the zinc element to the tin element ranges from 3.8:1 to 4.2:1; and
the first sub-layer includes at least zinc, indium, gallium and oxygen elements, a molar ratio of the indium element to the gallium element ranges from 0.8:1 to 1.2:1, and at molar ratio of the gallium element to the zinc element ranges from 0.8:1 to 1.2:1.

In some implementations, the gate is located on a side of the active layer away from the base substrate, and the thin film transistor further includes:
a first light-shielding layer located between the active layer and the base substrate, an orthographic projection of the first light-shielding layer on the base substrate is overlapped with an orthographic projection of the channel portion on the base substrate, and the first light-shielding layer is electrically connected with the gate.

In some implementations, the orthographic projection of the first light-shielding layer on the base substrate covers and exceeds the orthographic projection of the channel portion on the base substrate.

In some implementations, an overlapping area of the first light-shielding layer and the channel portion is less than or equal to an area of the orthographic of the channel portion on the base substrate; and
the thin film transistor further includes:
a second light-shielding layer located between the first light-shielding layer and the base substrate, and an orthographic projection of the second light-shielding layer on the base substrate covers and exceeds the orthographic projection of the channel part on the base substrate.

In some implementations, the first light-shielding layer includes: a first conductive layer, a second conductive layer and a third conductive layer which are sequentially stacked along a direction close to the base substrate, the first conductive layer being located on a side, away from the base substrate, of the second conductive layer, and a chemical activity of the first conductive layer being lower than that of the second conductive layer; an adhesive force between the third conductive layer and the base substrate being larger than that between the second conductive layer and the base substrate.

In some implementations, the gate is located in a gate metal layer, a gate insulating layer is disposed between the gate and the active layer, and an orthographic projection of the gate insulating layer on the base substrate does not exceed an orthographic projection of the gate metal layer on the base substrate.

In some implementations, a width of the channel portion in a predetermined direction is equal to a width of the gate in the predetermined direction, the predetermined direction being a direction from the first conductive portion toward the second conductive portion.

The present disclosure further provides a display substrate, which includes the thin film transistor described above, where
the display substrate further includes a gate line, a data line and a pixel electrode which are arranged on the base substrate, the gate of the thin film transistor is connected with the gate line, the first conductive portion is electrically connected with the data line, and the second conductive portion is electrically connected with the pixel electrode.

In some implementations, the active layer is located on a side of a layer where the data line is located away from the base substrate, the gate is located on a side of the active layer away from the base substrate, and the pixel electrode is located on a side of a layer where the gate is located away from the base substrate, and where
the display substrate further includes:
a buffer layer located between the layer where the data line is located and a layer where the active layer is located;
an insulating spacing layer located between the layer where the gate is located and a layer where the pixel electrode is located; and
a first transfer electrode located in the same layer as the pixel electrode, and electrically connects the first conductive portion with the data line through a first via hole;
the first via hole penetrating through the buffer layer and the insulating spacing layer, and exposing at least part of the first conductive portion and at least part of the data line.

In some implementations, the thin film transistor further includes:
a first light-shielding layer located in the same layer as the data line, where an orthographic projection of the first light-shielding layer on the base substrate is overlapped with an orthographic projection of the channel part on the base substrate.

In some implementations, the display substrate further includes:
a gate connection portion connected with the gate as an integral structure, the gate connection portion being electrically connected with the first-shielding layer through a second via hole.

In some implementations, the gate connection portion is located on a side of the gate line away from the active layer; or,
the gate and the gate connection portion are arranged along a direction in which the gate line extends; or,
the gate is a portion of the gate line, and the gate connection portion is located at a side of the gate line in a width direction of the gate line.

In some implementations, the display substrate further includes:
a gate connection portion connected with the gate as an integral structure;
a second transfer electrode located in the same layer as the pixel electrode and electrically connects the gate connection portion with the first-shielding layer through a third via hole;
the third via hole exposes at least a portion of the gate connection portion and at least a portion of the first light-shielding layer.

The present disclosure further provides a method for manufacturing a display substrate, including:
forming a data line on a base substrate;
forming an active layer of a thin film transistor on the base substrate;
forming a gate line and a gate of the thin film transistor on the base substrate, the gate being electrically connected with the gate line;
forming a pixel electrode on the base substrate;
where, the active layer includes: a first conductive portion, a second conductive portion and a channel part connected between the first conductive portion and the second conductive portion, the channel portion and the gate being oppositely arranged and insulated from each other, the gate being electrically connected with the gate line, the first conductive portion being electrically connected with the data line, and the second conductive portion being electrically connected with the pixel electrode; and a material of the active layer includes a metal oxide MxNyOz, M and N respectively including any one or more of zinc, indium, gallium, tin and lanthanide metals, O being oxygen, x, y and z being natural numbers greater than 0, and 0.8≤x+y+z≤1.0.

In some implementations, the active layer is formed after the data line is formed, the gate is formed after the active layer is formed, and the pixel electrode is formed after the gate is formed;
the method further includes:
forming a buffer layer, the buffer layer being located between a layer where the data line is located and a layer where the active layer is located;
forming an insulating spacing layer, the insulating spacing layer being located between a layer where the gate is located and a layer where the pixel electrode is located;
forming a first via hole penetrating through the insulating spacing layer and the buffer layer, the first via hole exposing at least a portion of the first conductive portion and at least a portion of the data line; and
forming a first transfer electrode, the first transfer electrode electrically connecting the first conductive portion with the data line through the first via hole, where the first transfer electrode and the pixel electrode are formed in synchronization.

In some implementations, the method further includes:
forming a first light-shielding layer while forming the data line, where, an orthographic projection of the first light-shielding layer on the base substrate is overlapped with an orthographic projection of the channel portion on the base substrate.

In some implementations, the method further including:
forming a gate connection portion, the gate connection and the gate being connected as an integral structure;
forming a third via hole, the third via hole penetrating through the buffer layer and the insulating spacing layer between the pixel electrode and the layer where the first-shielding layer is located, and exposing at least part of the gate connection portion and at least part of the first-shielding layer; and
forming a second transfer electrode while forming the pixel electrode, the second transfer electrode electrically connecting the gate connection portion with the first-shielding layer through the third via hole.

The present disclosure further provides a display device including the display substrate described above.

### BRIEF DESCRIPTION OF DRAWINGS

The accompanying drawings are included to provide a further understanding of the embodiments of the present disclosure, and are incorporated in and constitute a part of the description, illustrate embodiments of the present disclosure and together with the description serve to explain the present disclosure and not to limit the present disclosure, in the drawings:

FIG. 1 is a partial plan view of a pixel region provided in some embodiments of the present disclosure.

FIG. 2 is a partial plan view of a pixel region provided in some embodiments of the present disclosure.

FIG. 3 is a cross-sectional view of a structure of FIG. 1 taken along a line A-A′.

FIG. 4 is another cross-sectional view of the structure of FIG. 1 taken along a line A-A′.

FIG. 5 shows a comparison between resistance values of different active layer structures after being transformed into conductors.

FIG. 6 shows current-voltage (I-V) characteristic curves of the thin film transistors in FIG. 3 and FIG. 4.

FIG. 7 is a plan view of a thin film transistor in some embodiments of the present disclosure.

FIG. 8 is a plan view of a thin film transistor in other embodiments of the present disclosure.

FIG. 9 is a cross-sectional view of the structure of FIG. 7 taken along a line B-B′.

FIG. 10 shows a comparison between resistance values of different active layer structures after being transformed into conductors.

FIG. 11 is a plan view of a thin film transistor in other embodiments of the present disclosure.

FIG. 12 is a cross-sectional view of the structure of FIG. 11 taken along a line C-C′.

FIG. 13 shows current-voltage (I-V) curves of a dual-gate transistor and a single-gate transistor.

FIG. 14 shows current-voltage (I-V) curves of different dual-gate transistors.

FIG. 15 is a plan view of a thin film transistor in other embodiments of the present disclosure.

FIG. 16 is a cross-sectional view of a structure in FIG. 15 taken along a line D-D′.

FIG. 17 is a cross-sectional view of a first light-shielding layer in some embodiments of the present disclosure.

FIG. 18 is a schematic view of a display substrate in some embodiments of the present disclosure.

FIG. 19 is a schematic diagram showing a connection between a thin film transistor and a data line, a gate line, and a pixel electrode in a first embodiment of the present disclosure.

FIG. 20 is another schematic diagram showing a connection between the thin film transistor and the data line, the gate line and the pixel electrode in the first embodiment of the present disclosure.

FIG. 21 is a cross-sectional view of a structure in FIG. 19 taken along a line E-E′.

FIG. 22 is a schematic diagram showing a connection between a thin film transistor and a data line, a gate line, and a pixel electrode in a second embodiment of the present disclosure.

FIG. 23 is another schematic diagram showing a connection between the thin film transistor and the data line, the gate line and the pixel electrode in the second embodiment of the present disclosure.

FIG. 24 is a cross-sectional view of the structure in FIG. 22 taken along a line F-F′.

FIG. 25 is a schematic diagram showing a connection between a thin film transistor and a data line, a gate line, and a pixel electrode in a third embodiment of the present disclosure.

FIG. 26 is schematic diagram showing a connection between the thin film transistor and the data line, the gate line, and the pixel electrode in the third embodiment of the present disclosure.

FIG. 27 is a cross-sectional view of the structure in FIG. 25 taken along a line G-G′.

FIG. 28 is a schematic diagram showing a connection between a thin film transistor and a data line, a gate line, and a pixel electrode in a fourth embodiment of the present disclosure.

FIG. 29 is another schematic diagram showing a connection between the thin film transistor and the data line, the gate line, and the pixel electrode in the fourth embodiment of the present disclosure.

FIG. 30 is a cross-sectional view of the structure in FIG. 28 taken along a line H-H′.

FIG. 31 is a schematic diagram showing a connection between a thin film transistor and a data line, a gate line, and a pixel electrode in a fifth embodiment of the present disclosure.

FIG. 32 is a cross-sectional view of the structure in FIG. 31 taken along a line I-I′.

FIG. 33 is a flowchart of a method for manufacturing a display substrate according to an embodiment of the present disclosure.

FIGS. 34A to 34J are schematic diagrams illustrating a first method for manufacturing a display substrate.

FIGS. 35A to 35J are schematic diagrams illustrating a second method for manufacturing a display substrate.

FIGS. 36A to 36J are schematic diagrams illustrating a third method for manufacturing a display substrate.

FIGS. 37A to 37J are schematic diagrams illustrating a fourth method for manufacturing a display substrate.

FIGS. 38A to 38B are schematic diagrams illustrating a part of steps of a fifth method for manufacturing a display substrate.

### DETAIL DESCRIPTION OF EMBODIMENTS

Specific embodiments of the present disclosure will be described in detail below in conjunction with the accompanying drawings. It should be understood that the specific embodiments described herein are only for illustration and explanation of the present disclosure, and are not intended to limit the present disclosure.

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few embodiments of the present disclosure, and not all embodiments. All other embodiments, which can be derived by a person skilled in the art from the described embodiments of the present disclosure without creative effort, are within the protection scope of the present disclosure.

Unless defined otherwise, technical or scientific terms used herein shall have the ordinary meaning as understood by a person skilled in the art to which the present disclosure belongs. The use of “first”, “second”, and the like in this disclosure is not intended to indicate any order, quantity, or importance, but rather is used to distinguish one element from another. Also, the word “comprising/including” or “comprises/includes”, or the like, means that the element or item preceding the word includes the element or item listed after the word and its equivalent, but does not exclude other elements or items. The term “connected/coupled” or “connecting/coupling” or the like is not restricted to physical or mechanical connections, but may include electrical connections, whether direct or indirect. The words “upper”, “lower”, “left”, “right”, and the like are used only to indicate relative positional relationships, and when the absolute position of the object being described is changed, the relative positional relationships may also be changed accordingly.

As used herein, “being parallel” and “being perpendicular” include the situations described as well as situations that are similar to the described situations, and a range of the similar situations is within an acceptable deviation range, where the acceptable deviation range is determined by a person skilled in the art considering the measurement being discussed and an error related to the measurement of a specific quantity (i.e., the limitation of the measurement system). For example, the “being parallel” includes being absolutely parallel and being approximately parallel, where the acceptable deviation range for the being approximately parallel may indicate that the error is less than 5 degrees; and “being perpendicular” includes being absolutely perpendicular and being approximately perpendicular, where the acceptable deviation range for being approximately perpendicular may also indicate that the error is less than 5 degrees.

It will be understood that when a layer or element is referred to as being “on” another layer or a substrate, the layer or element may be directly on the another layer or the substrate, or intervening layers may further be present therebetween.

Example embodiments are described herein with reference to cross-sectional and/or plan views as idealized example drawings. In the drawings, thicknesses of layers and regions are exaggerated for clarity. Variations from the illustrated shapes in the drawings as a result, for example, of manufacturing techniques and/or tolerances, can be imaged. Thus, the example embodiments should not be construed as limited to the shapes of regions illustrated herein but are to include deviations in shapes that result, for example, from manufacturing. For example, etched regions shown as rectangles typically have curved features. Thus, the regions illustrated in the drawings are schematic in nature and their shapes are not intended to illustrate the actual shapes of the regions of a device and are not intended to limit the scope of exemplary embodiments.

It should be noted that “disposed in the same layer” in the embodiments of the present disclosure means that two structures are formed by a same material layer through a single patterning process, and therefore, the two structures are located in the same layer in terms of a stacking relationship, but this does not mean that distances from the two structures to a base substrate must be the same.

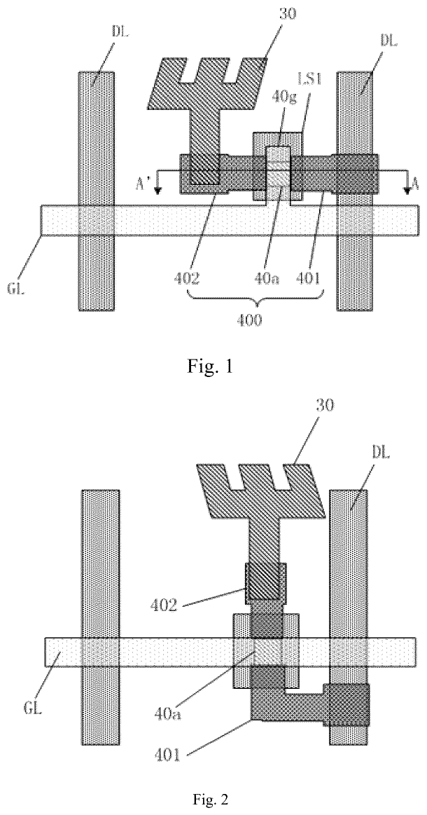

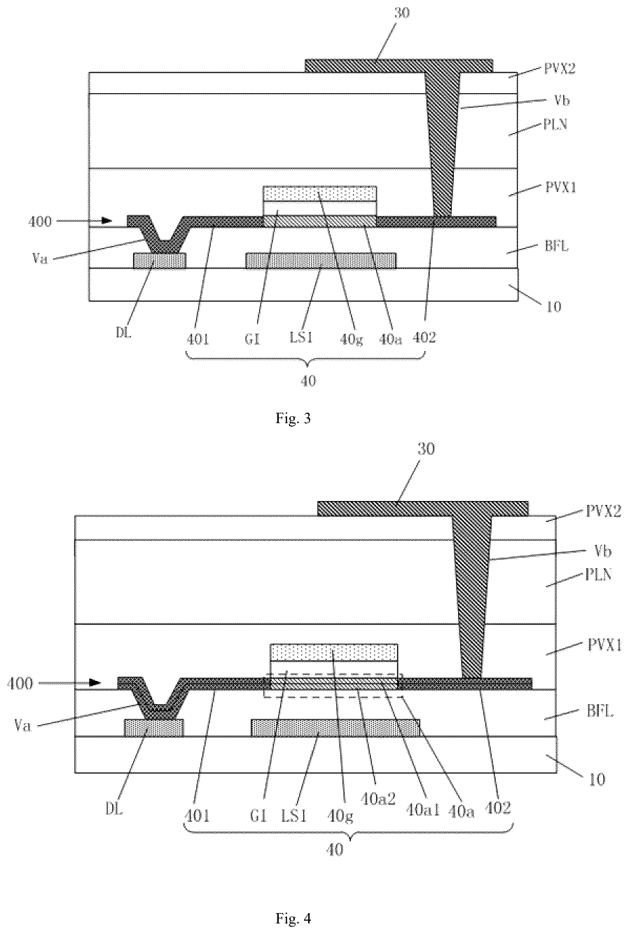

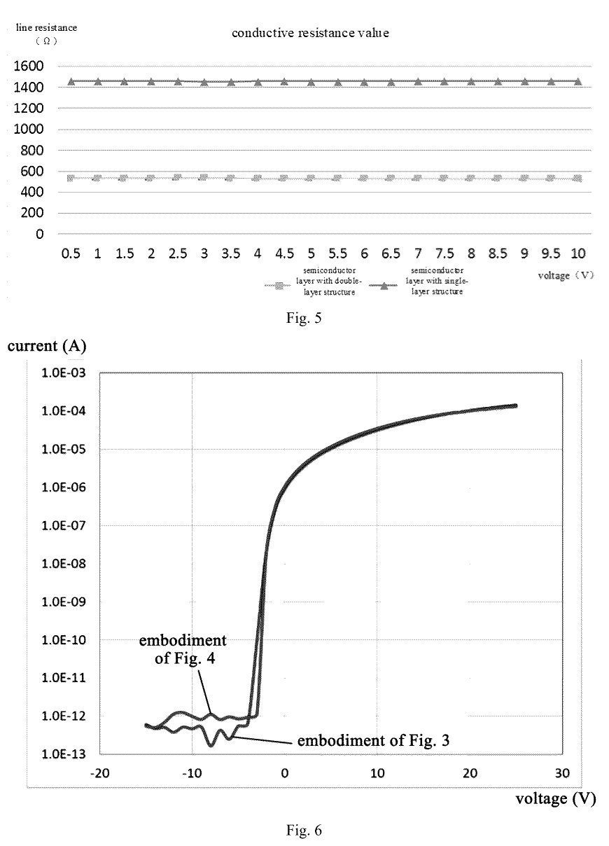

The present disclosure provides a thin film transistor that may be provided in a display region or a non-display region. The embodiments of the present disclosure are described by taking a case in which a thin film transistor is provided in the display region as an example. In a display substrate, a plurality of gate lines and a plurality of data lines are intersected with each other, so as to define a plurality of pixel regions, and each pixel region corresponds to one thin film transistor. FIG. 1 is a partial plan view of a pixel region provided in some embodiments of the present disclosure, FIG. 2 is a partial plan view of a pixel region provided in other embodiments of the present disclosure, and FIG. 3 is a cross-sectional view of the structure in FIG. 1 taken along a line A-A′, and as shown in FIGS. 1 to 3, a pixel electrode 30 is disposed in each pixel region, a gate 40g of a thin film transistor 40 is connected to a gate line GL, a source of the thin film transistor 40 is connected to a data line DL, and a drain of the thin film transistor 40 is connected to the pixel electrode 30. When the gate line GL receives a scan signal, the thin film transistor 40 is turned on, so that a data voltage in the data line DL is transmitted to the pixel electrode 30.

As shown in FIG. 3, the active layer 400 includes a channel portion 40a, and a first conductive portion 401 and a second conductive portion 402 located at two sides of the channel portion 40a, where the first conductive portion 401 and the second conductive portion 402 are formed by transforming semiconductor materials into conductors, and the first conductive portion 401 may serve as a source of the thin film transistor 40 and is electrically connected to the data line DL; the second conductive portion 402 may serve as a drain of the thin film transistor 40 and is electrically connected to the pixel electrode 30.

The active layer 400 may be straight line-shaped as shown in FIG. 1, or may be L-shaped as shown in FIG. 2.

In an example, as shown in FIG. 3, the thin film transistor 40 may further include a first light-shielding layer LS1, the first light-shielding layer LS1 is located between the channel portion 40a and the base substrate 10, and an orthographic projection of the first light-shielding layer LS1 on the base substrate 10 overlaps an orthographic projection of the channel portion 40a on the base substrate 10, so as to reduce a leakage current of the thin film transistor 40 due to the light irradiation on the channel portion 40a.

In an example, the first light-shielding layer LS1 may be disposed in the same layer as the data line DL, a buffer layer BFL is disposed between the active layer 400 and a layer where the first light-shielding layer LS1 is located, the gate 40g is located on a side of the active layer 400 away from the base substrate 10, and a gate insulating layer GI is disposed between the gate 40g and the active layer 400. The first conductive portion 401 is connected to the data line DL through a via hole Va penetrating through the buffer layer BFL. A first passivation layer PVX1, a planarization layer PLN, and a second passivation layer PVX2 are sequentially disposed on a side of the gate 40g away from the base substrate 10, and the pixel electrode 30 is located on a side of the planarization layer PLN and electrically connected to the second conductive portion 402 through a via hole Vb.

In the embodiments of the present disclosure, a material of the active layer 400 may include a metal oxide MxNyOz, where M and N respectively include any one or more of zinc, indium, gallium, tin, and lanthanide metals, O is an oxygen element, x, y, and z are natural numbers greater than 0, and 0.8≤x+y+z≤1.0. It should be noted that, the x, y and z represent an molar ratio or mass fraction of M, N, O elements in the entire metal oxide, respectively. By doping any one or more of zinc, indium, gallium, tin and lanthanide metals in the active layer 400, a hall mobility of the active layer 400 can be improved, and the hall mobility may be greater than 30 cm²/(v·s), so that a width-to-length ratio of the channel portion 40a can be reduced, which is favorable for reducing a size of the thin film transistor 40 and improving the resolution of the display substrate. In addition, by doping the active layer 400 with any one or more of zinc, indium, gallium, tin, and lanthanoid metals, the stability of the channel portion 40a under light irradiation can be improved.

In some implementations, x+y+z ranges from about 0.85 to about 0.99, thereby further improving the hall mobility of the active layer 400. It should be noted that “about” means within ±20% of the numerical value. For example, “about” 0.8 means 80% to 120% of 0.8.

In some implementations, the active layer 400 is a single-layer structure, and the active layer 400 is made of Indium gallium zinc tin oxide (IGZTO) including at least zinc, indium, gallium, tin, and oxygen, where a molar ratio of the indium element to the gallium element ranges from about 3.6:1.2 to about 4.0:1.2, a molar ratio of the gallium element to the zinc element ranges from about 1:4 to about 1.4:4, and a molar ratio of the zinc element to the tin element ranges from about 3.8:1 to about 4.2:1. For example, the molar ratio of the indium element to the gallium element is about 3.6:1.2, or about 3.8:1.2, or about 4.0:1.2; the molar ratio of the gallium element to the zinc element is about 1:4, or about 1.1:4, or about 1.2:4, or about 1.4:4. The molar ratio of the zinc element to the tin element is about 3.8:1, or about 4.0:1, or about 4.2:1.

Herein, “about” a certain proportion refers to 80% to 120% of the proportion.

FIG. 4 is another cross-sectional view of the structure in FIG. 1 taken along a line A-A′. In other embodiments, as shown in FIG. 4, the active layer 400 includes a first sub-layer 40a1 and a second sub-layer 40a2, where the first sub-layer 40a1 is closer to the gate 40g than the second sub-layer 40a2, and the hall mobility of the second sub-layer 40a2 may be greater than the hall mobility of the first sub-layer 40a1. For example, the first sub-layer 40a1 may include indium gallium zinc oxide (IGZO), and the first sub-layer 40a1 includes at least indium (In), gallium (Ga), zinc (Zn), and oxygen (O) elements therein. In the first sub-layer 40a1, a molar ratio of indium to gallium is about 0.8:1 to about 1.2:1, and a molar ratio of gallium to zinc is about 0.8:1 to about 1.2:1. The second sub-layer 40a2 may include indium gallium zinc tin oxide (IGZTO), and the second sub-layer 40a2 includes at least zinc, indium, gallium, tin, and oxygen elements, where a molar ratio of the indium element to the gallium element ranges from about 3.6:1.2 to about 4.0:1.2, a molar ratio of the gallium element to the zinc element ranges from about 1:4 to about 1.4:4, and a molar ratio of the zinc element to the tin element ranges from about 3.8:1 to about 4.2:1.

In a case where the active layer 400 is of a single-layer structure and is made of a metal oxide with high mobility, the stability of its own characteristics is easily affected by other processes, for example, a high temperature during a film formation process of the gate insulating layer GI may cause the channel portion 40a to become conductor so as to lose the semiconductor characteristics; meanwhile, resistances of the first conductive portion 401 and the second conductive portion 402 formed after the formation of the conductor is easily increased. In the embodiment shown in FIG. 4, in a case where the active layer 400 is provided as a multi-layer structure including a metal oxide with a relatively high mobility and a metal oxide with a relatively low mobility, the first sub-layer 40a1 can protect the second sub-layer 40a2, so as to prevent the channel portion 40a from transforming into a conductor by a high temperature during the preparation of the insulating layer.

Note that the materials of the first sub-layer 40a1 and the second sub-layer 40a2 in FIG. 4 may be interchanged, so that it is possible to prevent the channel portion 40a from transforming into a conductor due to the high temperature during the preparation of the insulating layer under the channel portion 40a.

FIG. 5 shows a comparison between resistance values of different active layer structures after being transformed into conductors. In FIG. 5, the vertical axis represents line resistances, in the unit of ohm, of the active layer structures after being transformed into conductors. The horizontal axis represents voltages in the unit of V. The two curves are respectively a curve of variation of the resistance value of the active layer with the single-layer structure after being transformed into conductor with voltage, and a curve of variation of the resistance value of the active layer with the double-layer structure after being transformed into conductor with voltage. In some implementations, the active layer of the single-layer structure includes the IGZTO layer, and in the active layer of the double-layer structure, the lower one includes IGZTO, and the upper one includes IGZO. As can be seen from FIG. 5, in a case where the active layer 400 is of the double-layer structure, the resistances of the first conductive portion 401 and the second conductive portion 402 formed after transforming the first sub-layer and the second sub-layer into conductors is significantly reduced. FIG. 6 shows current-voltage (I-V) characteristic curves of the thin film transistors in FIG. 3 and FIG. 4, where the width-to-length ratio of the thin film transistor is 5/4, as can be seen from FIG. 6, in a case where the active layer 400 adopts the double-layer structure, a subthreshold swing of the thin film transistor 40 is smaller, and a transfer characteristic of the thin film transistor 40 is better.

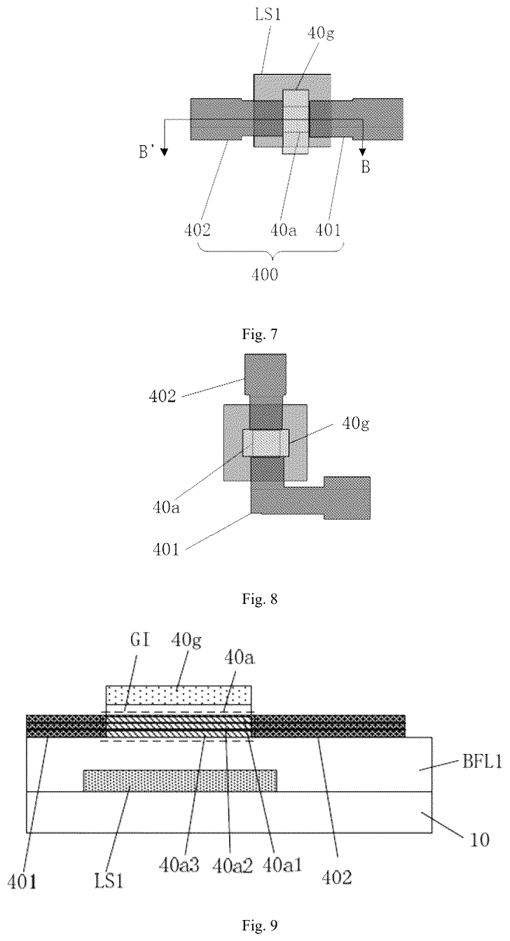

FIG. 7 is a plan view of a thin film transistor provided in some embodiments of the present disclosure, FIG. 8 is a plan view of a thin film transistor provided in other embodiments of the present disclosure, and FIG. 9 is a cross-sectional view of the structure of FIG. 7 taken along a line B-B′. As shown in FIGS. 7 to 9, the thin film transistor 40 includes a gate 40g and an active layer 400, where the active layer 400 includes: a first conductive portion 401, a second conductive portion 402, and a channel portion 40a connected between the first conductive portion 401 and the second conductive portion 402, the channel portion 40a being disposed opposite to the gate 40g and being insulated from the gate 40g. For example, a gate insulating layer GI is provided between the channel portion 40a and the gate 40g.

In some implementations, the active layer includes a first sub-layer 40a1, a second sub-layer 40a2 and a third sub-layer 40a3, which are sequentially disposed in a direction close to base substrate 10. Materials of the first sub-layer 40a1, the second sub-layer 40a2, and the third sub-layer 40a3 all include metal oxides, and the mobility of the first sub-layer 40a1 and the mobility of the third sub-layer 40a3 are both smaller than the mobility of the second sub-layer 40a2.

In the embodiments of the present disclosure, the second sub-layer 40a2 may adopt the metal oxide having high mobility, and in this case, even if the width-to-length ratio of the channel portion 40a is reduced, the characteristics of the thin film transistor 40 are not affected, thereby facilitating the realization of high resolution of a display product. Moreover, since the third sub-layer 40a3 and the first sub-layer 40a1 are respectively disposed on an upper side and a lower side of the second sub-layer 40a2, and the mobility of the first sub-layer 40a1 and the mobility of the third sub-layer 40a3 are both smaller than the mobility of the second sub-layer 40a2, therefore, the third sub-layer 40a3 and the first sub-layer 40a1 can protect the second sub-layer 40a2, thereby reducing or preventing the occurrence of the situation that the channel portion 40a is transformed into conductor due to high temperature during the process of preparing the insulating layers above and below the active layer 400.

In some implementations, during the preparation of the active layer 400, in the regions where the first conductive portion 401 and the second conductive portion 402 are to be formed, the first sub-layer 40a1, the second sub-layer 40a2, and the third sub-layer 40a3 are transformed into conductors, so that the first conductive portion 401 and the second conductive portion 402 are formed, and portions of the first sub-layer 40a1, the second sub-layer 40a2, and the third sub-layer 40a3 that are not transformed into conductors constitute the channel portion 40a.

In some implementations, the second sub-layer 40a2 includes indium gallium zinc tin oxide (IGZTO); the first sub-layer 40a1 and the third sub-layer 40a3 each include indium gallium zinc oxide (IGZO), so that the second sub-layer 40a2 has a high mobility, and the mobility of the first sub-layer 40a1 and the third sub-layer 40a3 is smaller than that of the second sub-layer 40a2.

In some implementations, in the second sub-layer 40a2, a molar ratio of the indium element to the gallium element ranges from about 3.6:1.2 to about 4.0:1.2, and a molar ratio of the gallium element to the zinc element ranges from about 1:4 to about 1.4:4, a molar ratio of the zinc element to the tin element ranges from about 3.8:1 to about 4.2:1. For example, the molar ratio of the indium element to the gallium element is about 3.6:1.0, or about 3.6:1.2, or about 3.8:1.2, or about 4.0:1.2.

In either of the first sub-layer 40a1 and the third sub-layer 40a3, the molar ratio of the indium element to the gallium element ranges from about 0.8:1 to about 1.2:1, and the mole ratio of the gallium element to the zinc element ranges from about 0.8:1 to about 1.2:1. For example, in either of the first sub-layer 40a1 and the third sub-layer 40a3, the molar ratio of the indium element to the gallium element is about 0.8:1, or about 0.9:1, or about 1.0:1; and molar ratio of the gallium element to the zinc element is about 0.8:1, or about 1.0:1 or about 1.2:1.

In a preferred implementation, in the second sub-layer 40a2, the molar ratio of the indium element, the gallium element and the zinc element is as follows: In:Ga:Zn=1:1:1. In the first sub-layer 40a1 and third sub-layer 40a3, the molar ratio of the indium element, the gallium element, the zinc element and the tin element is as follows: In:Ga:Zn:Sn=3.8:1.2:4:1.

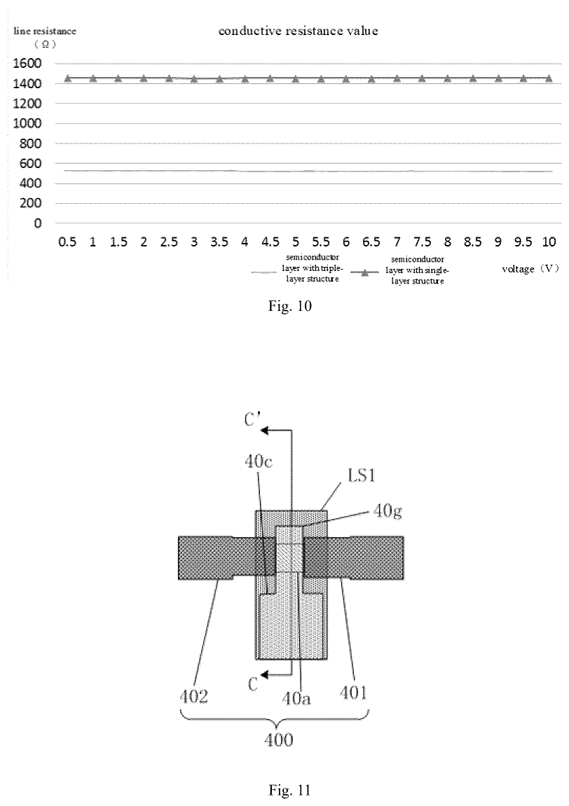

FIG. 10 shows a comparison between resistance values of different active layer structures after being transformed into conductors. In some implementations, the vertical axis represents line resistances, in the unit of ohm, of the active layer structures after being transformed into conductors. The horizontal axis represents voltages, in the unit of V. The two curves are respectively a curve of variation of the resistance value of the single-layer active layer structure after being transformed into conductor with voltage, and a curve of variation of the resistance value of a triple-layer active layer structure after being transformed into conductor with voltage. The single-layer active layer includes IGZTO, the triple-layer active layer includes the first sub-layer 40a1, the second sub-layer 40a2, and the third sub-layer 40a3 described above, the second sub-layer includes IGZTO, and the first sub-layer 40a1 and the third sub-layer 40a3 both include IGZO. As can be seen from FIG. 10, in a case where the active layer 400 adopts the triple-layer structure, the resistances of the first conductive portion 401 and the second conductive portion 402 formed after transforming the first sub-layer, the second sub-layer and the third sub-layer into conductors are significantly reduced.

As shown in FIG. 7, an orthographic projection of the active layer 400 on the base substrate 10 may be in a straight line shape; while as shown in FIG. 8, the orthographic projection of the active layer 400 on the base substrate 10 may alternatively be L-shaped.

As shown in FIG. 9, the gate 40g is located on a side of the active layer 400 away from the base substrate 10, and a material of the gate 40g may include a metal, a metal alloy, a metal nitride, a conductive metal oxide, a transparent conductive material, and the like. For example, the gate 40g may include any one or more of gold (Au), an alloy of gold, silver (Ag), an alloy of silver, aluminum (Al), an alloy of aluminum, aluminum nitride (AlNx), tungsten (W), tungsten nitride (WNx), copper (Cu), an alloy of copper, nickel (Ni), chromium (Cr), chromium nitride (CrNx), molybdenum (Mo), an alloy of molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), Tin oxide (SnOx), indium oxide (InOx), gallium oxide (GaOx), Indium TiN Oxide (ITO), Indium Zinc Oxide (IZO), molybdenum titanium niobium (MTD), and the like. The gate 40g may be of a single-layer structure or a multi-layer structure.

In some implementations, the gate 40g may be located in a gate metal layer, and the gate metal layer may include other structures, such as a gate line, a common electrode line, and the like, besides the gate 40g of the thin film transistor 40.

A gate insulating layer GI is disposed between the gate 40g and the active layer 400, and the gate insulating layer GI may include silicon oxynitride (SiON), silicon oxide (SiOx), silicon nitride (SiNx), silicon oxycarbide (SiOxCy), silicon carbonitride (SiCxNy), aluminum oxide (A1Ox), aluminum nitride (AlNx), tantalum oxide (TaOx), hafnium oxide (HfOx), zirconium oxide (ZrOx), titanium oxide (TiOx), and the like. The gate insulating layer GI may be formed into a single-layer structure or a multiple-layer structure.

In some implementations, an orthographic projection of the gate insulating layer GI on the base substrate 10 does not exceed an orthographic projection of the gate metal layer on the base substrate 10. For example, the orthographic projection of the gate insulating layer GI on the base substrate 10 may coincide with the orthographic projection of the gate metal layer GI on the base substrate 10. Certainly, the gate insulating layer GI may alternatively be a continuous film layer which is an entire layer.

In some implementations, an orthographic projection of the channel portion 40a on the base substrate 10 is located within an orthographic projection of the gate 40g on the base substrate 10. In an example, a width of the channel portion 40a in a predetermined direction, which is a direction from the first conductive portion 401 to the second conductive portion 402, is equal to a width of the gate 40g in the predetermined direction. In this case, in the process of manufacturing the thin film transistor 40, a semiconductor intermediate pattern may be formed first; then, the gate 40g is formed, and then the semiconductor intermediate pattern is transformed into a conductor by using the gate 40g as a mask, thereby forming the active layer 400 including the channel portion 40a, the first conductive portion 401, and the second conductive portion 402.

In some implementations, as shown in FIGS. 7 to 9, the thin film transistor 40 further includes a first light-shielding layer LS1, where the first light-shielding layer LS1 is located between the active layer 400 and the base substrate 10, and an orthographic projection of the first light-shielding layer LS1 on the base substrate 10 overlaps with the orthographic projection of the channel portion 40a on the base substrate 10. For example, the orthographic projection of the first light-shielding layer LS1 on the base substrate 10 covers the orthographic projection of the channel portion 40a on the base substrate. The first light-shielding layer LS1 may have a single-layer structure or a multi-layer structure.

As shown in FIGS. 7 to 9, a first buffer layer BFL1 is disposed between the first light-shielding layer LS1 and the active layer 400, and the first buffer layer BFL1 may include an inorganic material such as silicon oxide (SiOx), silicon nitride (SiNx), and/or silicon oxynitride (SiON), and may be formed into a multi-layer structure or a single-layer structure.

In some implementations, the orthographic projection of the first light-shielding layer LS1 on the base substrate 10 covers the orthographic projection of the gate 40g on the base substrate 10, and in order to achieve a better light shielding effect, the orthographic projection of the first light-shielding layer LS1 on the base substrate 10 exceeds the orthographic projection of the gate 40g on the base substrate 10. For example, the orthographic projections of the first light-shielding layers LS1 on the base substrate and the orthographic projections of the gate 40g on the base substrate are both rectangular, and an interval of at least 4um exists between each side of the orthographic projection of the first light-shielding layers LS1 on the base substrate and each side, adjacent to the side of the orthographic projection of the first light-shielding layers LS1 on the base substrate, of the orthographic projection of the gate 40g on the base substrate.

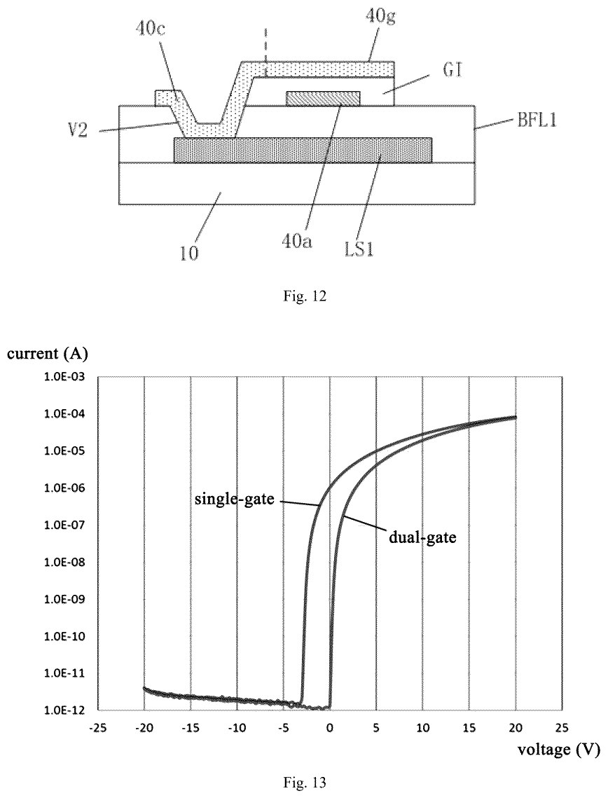

FIG. 11 is a plan view of a thin film transistor provided in other embodiments of the present disclosure, and FIG. 12 is a cross-sectional view of the structure of FIG. 11 taken along a line C-C′, and the structure of the thin film transistor 40 shown in FIG. 12 is similar to that of FIG. 9 except that, in FIG. 12, the gate 40g of the thin film transistor 40 is electrically connected to the first light-shielding layer LS1.

For example, as shown in FIGS. 11 and 12, the thin film transistor 40 may further include a gate connection portion 40c, being formed as an integral structure with the gate 40g (that is, the gate connection portion 40c and the gate 40g are formed into a single piece), the gate connection portion 40c being electrically connected to the first light-shielding layer LS1 through a second via hole V2 penetrating through the first buffer layer BFL 1.

Due to the difference in work functions between the metal and the metal oxide, when no voltage is applied to the first light-shielding layer LS1, that is, the first light-shielding layer LS1 is in a floating state, which may affect the channel portion 40a with high mobility, causing negative drift in the characteristics of the thin film transistor 40 with the single-gate structure. In the structures of FIGS. 11 and 12, the first light-shielding layer LS1 is electrically connected to the gate 40g, thereby forming the thin film transistor 40 with a dual-gate structure and alleviating the problem of negative drift of the initial characteristics of the thin film transistor 40. Meanwhile, the thin film transistor 40 with the dual-gate structure can greatly improve the on-state current and the mobility of the thin film transistor 40, thereby further improving the refresh rate of a display screen.

FIG. 13 shows current-voltage (I-V) curves of a dual-gate transistor and a single-gate transistor, in which the active layers 400 of the dual-gate transistor and the single-gate transistor in FIG. 13 adopt the double-layer structure of FIG. 4. As can be seen from FIG. 13, a normalized on-state current of the dual-gate transistor 40 with a width-to-length ratio W/L=6/5 reaches 54.6 μA, and the on-state current of the single-gate transistor 40 with a width-to-length ratio W/L=5/4 can be calculated as 30.3 μA after eliminating the influence of the negative drift, and it can be seen that the on-state current of the thin film transistor 40 is increased by at least 1.8 times after the first light-shielding layer LS1 is electrically connected with the gate 40g.

In FIGS. 11 and 12, the active layer 400 may be of a single-layer structure or a multi-layer structure. For example, the active layer 400 may include only the second sub-layer 40a2 described above; alternatively, may include the second sub-layer 40a2 and the third sub-layer 40a3 of FIG. 9; alternatively, may include the first sub-layer 40a1, the second sub-layer 40a2, and the third sub-layer 40a3 of FIG. 9. Certainly, the active layer 400 may have more layers.

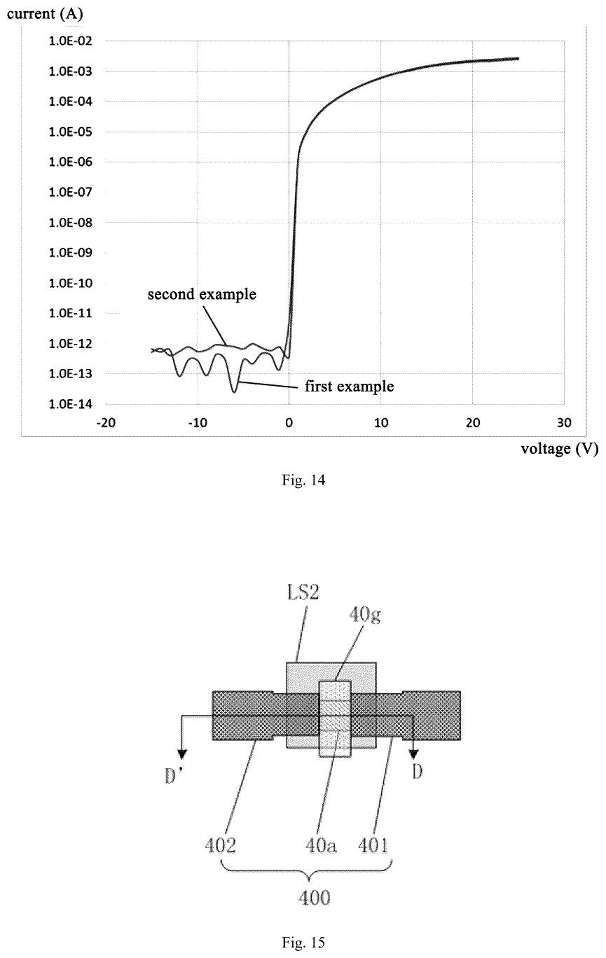

FIG. 14 shows current-voltage (I-V) curves of different dual-gate transistors, in FIG. 14, the dual-gate transistor 40 in the first example includes the active layer 400 which includes only the second sub-layer 40a2 as described above, and the dual-gate transistor 40 in the second example is of the structure shown in FIG. 4. It can be seen that the electrical characteristics of the dual-gate transistor 40 in which the active layer adopts the multi-layer structure are superior, compared to the dual-gate transistor 40 in which the active layer adopts the single-layer structure.

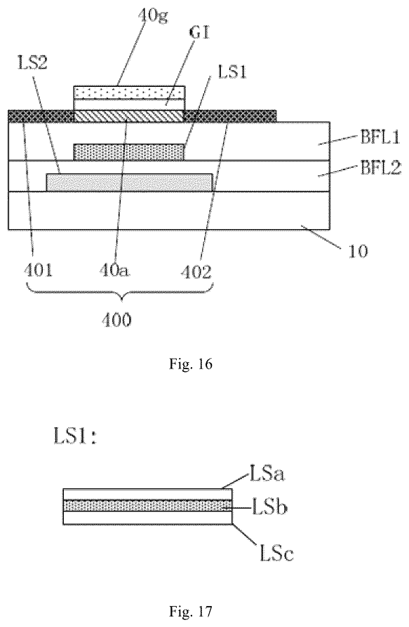

FIG. 15 is a plan view of a thin film transistor provided in other embodiments of the present disclosure, FIG. 16 is a cross-sectional view of a structure in FIG. 15 taken along a line D-D′, and the thin film transistor 40 shown in FIGS. 15 and 16 is similar to that shown in FIG. 9, except that the thin film transistor 40 in FIGS. 15 and 16 further includes a second light-shielding layer LS2 located between the first light-shielding layer LS1 and the base substrate 10, and a second buffer layer BFL2 is provided between the first light-shielding layer LS1 and the second light-shielding layer LS2.

In FIGS. 15 and 16, an overlapping area of the first light-shielding layer LS1 and the channel portion 40a is less than or equal to an area of the orthographic of the channel portion 40a on the base substrate 10. The overlapping area of the first light-shielding layer LS1 and the channel portion 40a is an area of a region where the orthographic projection of the first light-shielding layer LS1 on the base substrate 10 and the orthographic projection of the channel portion 40a on the base substrate 10 are overlapped. An orthographic projection of the second light-shielding layer LS2 on the base substrate 10 covers and exceeds the orthographic projection of the channel portion 40a on the base substrate 10.

In the embodiment shown in FIGS. 15 and 16, the overlapping area of the first light-shielding layer LS1 and the channel portion 40a is small, so that a magnitude of a parasitic capacitance formed by the first light-shielding layer LS1 and the channel portion 40a can be reduced. In addition, an area of the orthographic projection of the second light-shielding layer LS2 on the base substrate 10 is large, so that the channel portion 40a is ensured not to be irradiated with light.

In an example, the orthographic projection of the second light-shielding layer LS2 on the base substrate 10 may cover and exceed an orthographic projection of the gate 40g on the base substrate 10. For example, the orthographic projections of the gate 40g and the second light-shielding layer LS2 on the base substrate 10 are both rectangular, and there is an interval of at least 4 μm between each side of the orthographic projection of the gate 40g and a side, which is adjacent to the side of the orthographic projection of the gate 40g, of the orthographic projection of the second light-shielding layer LS2.

FIG. 17 is a cross-sectional view of a first light-shielding layer provided in some embodiments of the present disclosure, and in the embodiments, as shown in FIG. 17, the first light-shielding layer LS1 includes a first conductive layer LSa and a second conductive layer LSb which are stacked together, the first conductive layer LSa is located on a side of the second conductive layer LSb away from the base substrate 10, and chemical activity of the first conductive layer LSa is lower than that of the second conductive layer LSb. The second conductive layer LSb may include copper, and the first conductive layer LSa may include an alloy, and the first conductive layer LSa may prevent oxidation of a surface of the second conductive layer LSb, thereby preventing a problem of excessive contact resistance when the second conductive layer LSb is electrically connected to other structures.

In an example, the first light-shielding layer LS1 may further include a third conductive layer LSc, which is located on a side of the first conductive layer LSa away from the second conductive layer LSb, and an adhesive force of the third conductive layer LSc to the base substrate 10 is greater than an adhesive force of the second conductive layer LSb to the base substrate 10. It should be noted that the adhesive force of the third conductive layer LSc to the substrate base 10 being greater than the adhesive force of the second conductive layer LSb to the substrate base 10 does not mean that the third conductive layer LSc and the second conductive layer LSb are necessarily in contact with the substrate base 10 at the same time, but means that the adhesive force of the third conductive layer LSc to the substrate base 10 when the third conductive layer LSc contacts the substrate base 10 is greater than the adhesive force of the second conductive layer LSb to the substrate base 10 when the second conductive layer LSb contacts the substrate base 10. The second conductive layer LSb may include copper, and the third conductive layer LSc may include an alloy, for example, an alloy of Mo, Ti, Nb.

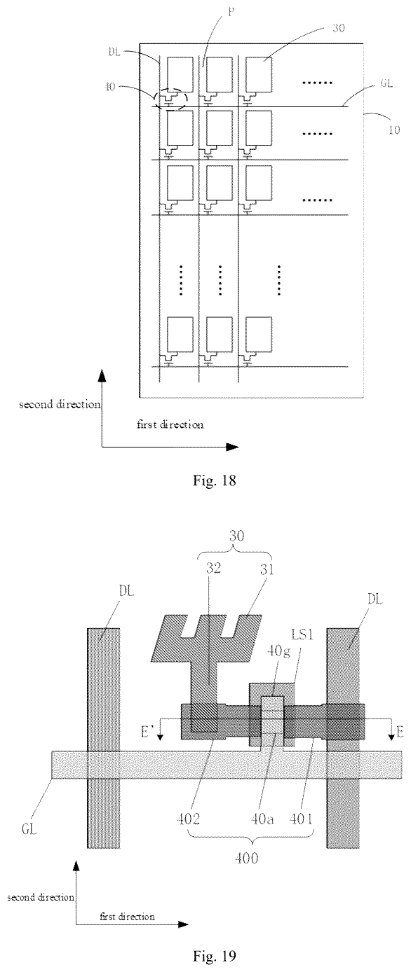

An embodiment of the present disclosure further provides a display substrate, which includes the thin film transistor 40 in the above embodiments. FIG. 18 is a schematic view of a display substrate provided in some embodiments of the present disclosure, and as shown in FIG. 18, the display substrate may include a plurality of gate lines GL extending in a first direction and a plurality of data lines DL extending in a second direction. The plurality of gate lines GL and the plurality of data lines DL are intersected each other, thereby defining a plurality of pixel regions P. Each pixel region P corresponds at least one thin film transistor 40.

In some implementations, as shown in FIG. 18, each pixel region P may corresponds one thin film transistor 40, and a pixel electrode 30 is disposed in each pixel region P. The gate 40g of the thin film transistor 40 is electrically connected to the gate line GL, the first conductive portion 401 of the thin film transistor 40 is electrically connected to the data line DL, and the second conductive portion 402 of the thin film transistor 40 is electrically connected to the pixel electrode 30. For example, the gate 40g may be integrated with the gate line GL (that is, the gate 40g and the gate line GL are formed into a single piece), and the first conductive portion 401 may be electrically connected to the data line DL through a via hole, and the pixel electrode 30 may be electrically connected to the second conductive portion 402 through a via hole.

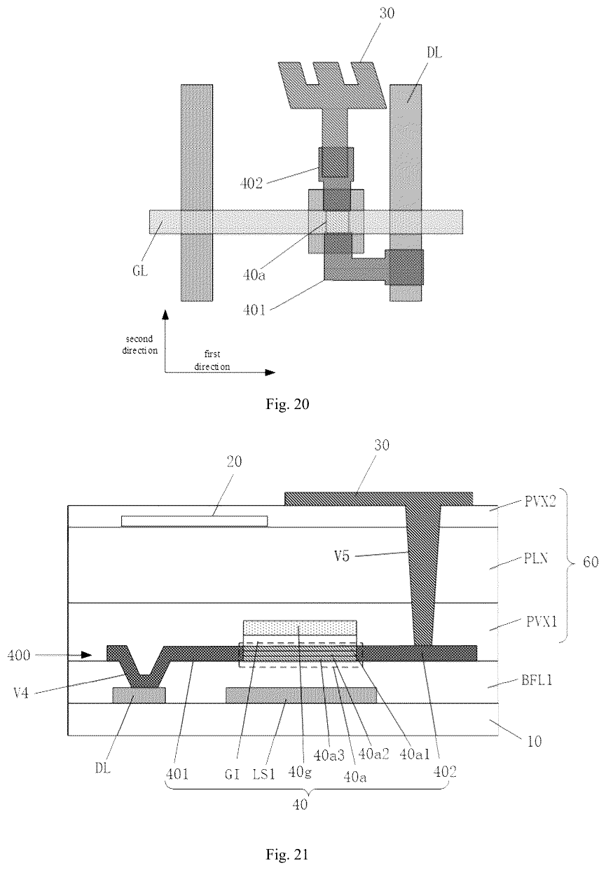

FIG. 19 is a schematic diagram showing a connection between a thin film transistor and a data line, a gate line and a pixel electrode in a first embodiment of the present disclosure, FIG. 20 is another schematic diagram showing a connection between a thin film transistor and a data line, a gate line and a pixel electrode in the first embodiment of the present disclosure, and FIG. 21 is a cross-sectional view of the structure in FIG. 19 taken along a line E-E′. As shown in FIGS. 19 to 21, in some embodiments, the thin film transistor 40 may adopt the thin film transistor 40 of FIGS. 7 to 8.

In some implementations, the first light-shielding layer LS1 is disposed in the same layer as the data line DL, so that the first light-shielding layer LS1 can be formed simultaneously with the data line DL to simplify the manufacturing process.

The first light-shielding layer LS1 and the data line DL are made of a same material. For example, the first light-shielding layer LS1 and the data line DL each include the first conductive layer LSa and the second conductive layer LSb, and the chemical activity of the first conductive layer LSa is less than that of the second conductive layer LSb, so that the data line DL can be prevented from being oxidized, and thus, the problem of too high contact resistance with the first conductive portion 401 due to the data line DL can be prevented.

In some implementations, as shown in FIG. 21, a first buffer layer BFL1 is disposed between a layer where the first light-shielding layer LS1 is located and the active layer 400; the first conductive portion 401 is connected to the data line DL through a fourth via hole V4 penetrating through the first buffer layer BFL1. The gate 40g is located on a side of the active layer 400 away from the base substrate 10, a gate insulating layer GI is disposed between the active layer 400 and a layer where the gate 40g is located, and the arrangement of the gate insulating layer GI may refer to the above description and is not described herein again.

An insulating spacing layer 60 is disposed on a side of the gate 40g away from the substrate base 10, and the pixel electrode 30 is disposed on a side of the insulating spacing layer 60 away from the substrate base 10 and electrically connected to the second conductive portion 402 of the active layer 400 through a fifth via hole V5.

In some implementations, the pixel electrode 30 may include an electrode main portion 31 and an electrode connecting portion 32 connected to each other, the electrode main portion 31 being located on a surface of the insulating spacing layer away from the base substrate 10, the electrode connecting portion 32 being electrically connected to the second conductive portion 402 through the fifth via hole V5.

In some implementations, the insulating spacing layer 60 may include: a first passivation layer PVX1, a planarization layer PLN, and a second passivation layer PVX2.

The first passivation layer PVX1 is located on a side of the layer where the gate 40g is located away from the base substrate 10, and a material of the first passivation layer PVX1 may include: silicon oxynitride (SiON), silicon oxide (SiOx), silicon nitride (SiNx), silicon oxycarbide (SiOxCy), silicon carbonitride (SiCxNy), aluminum oxide (AlOx), aluminum nitride (AlNx), tantalum oxide (TaOx), hafnium oxide (HfOx), zirconium oxide (ZrOx), titanium oxide (TiOx), and the like. The first passivation layer PVX1 may be formed into a single-layer structure or a multi-layer structure.

The planarization layer PLN is located on a side of the first passivation layer PVX1 away from the base substrate 10; a material of the planarization layer PLN may include an organic insulating material including, for example, resin-based materials such as polyimide, epoxy, acryl, polyester, photoresist, polyacrylate, polyamide, siloxane, and the like. As another example, the organic insulating material includes an elastic material, such as urethane, Thermoplastic Polyurethane (TPU), or the like.

The second passivation layer PVX2 is located on a side of the planarization layer PLN away from the base substrate 10. A material of the second passivation layer PVX2 can adopt the material of the first passivation layer PVX1 listed above, and the description thereof is omitted here.

In some implementations, as shown in FIG. 21, the display substrate further includes a common electrode 20, and the common electrode 20 is located between the planarization layer PLN and the second passivation layer PVX 2. An electric field may be generated between the common electrode 20 and the pixel electrode 30 to drive the liquid crystal in the display device to deflect.

The common electrode 20 and the pixel electrode 30 each may be made of a transparent conductive material such as Indium Tin Oxide (ITO).

In some implementations, the gate 40g is located on a side of the gate line GL in a width direction of the gate line GL; the active layer 400 has a line-shaped structure, and for example, an orthographic projection of the active layer 400 on the base substrate 10 may extend in a first direction. In other embodiments, the active layer 400 has an L-shaped structure, for example, the first conductive portion 401 and the channel portion 40a are aligned along the first direction, and the second conductive portion 402 and the channel portion 40a are aligned along a second direction.

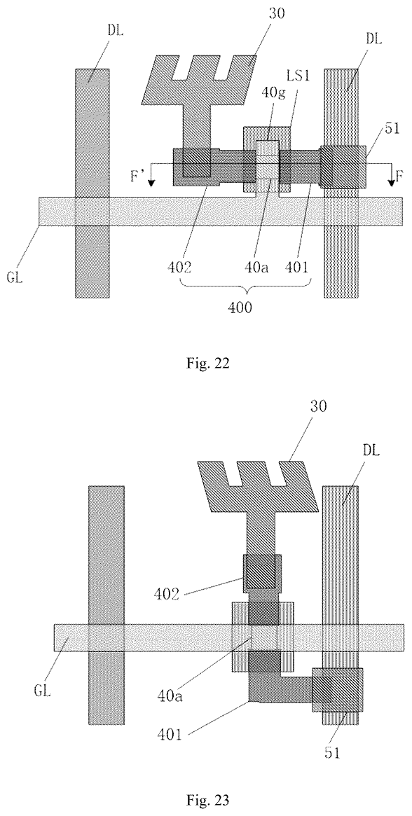

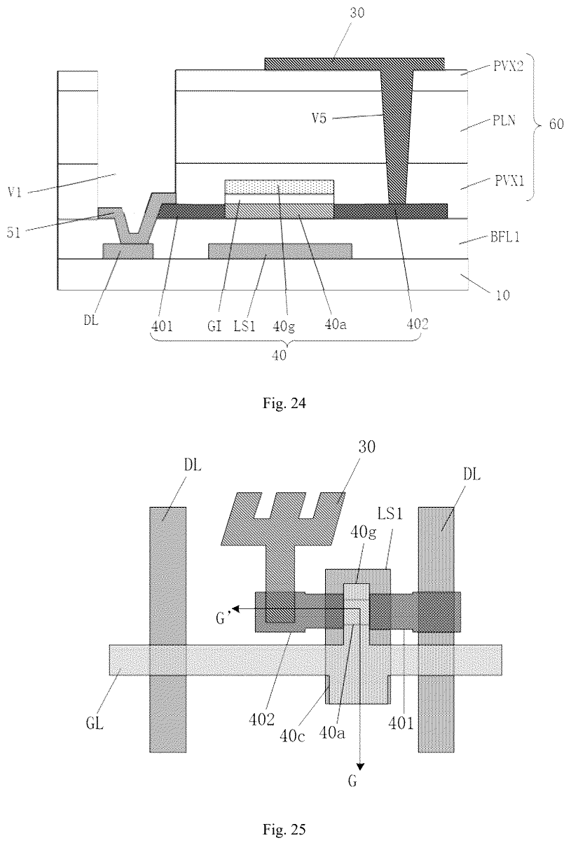

FIG. 22 is a schematic diagram showing a connection between a thin film transistor and a data line, a gate line and a pixel electrode in a second embodiment of the present disclosure, FIG. 23 is another schematic diagram showing a connection between the thin film transistor and the data line, the gate line, and the pixel electrode in the second embodiment of the present disclosure, FIG. 24 is a cross-sectional view of the structure in FIG. 22 taken along a line F-F′, and the display substrate shown in FIG. 24 is different from that shown in FIG. 21 in that the display substrate in FIG. 24 further includes a first transfer electrode 51, where the first conductive portion 401 of the thin film transistor 40 is electrically connected to the data line DL through the first transfer electrode 51. The first transfer electrode 51 and the pixel electrode 30 are located in a same layer, and the first transfer electrode 51 electrically connects the first conductive portion 401 to the data line DL through the first via hole V1. The first via hole V1 penetrates through the first buffer layer BFL1 and the insulating spacing layer 60 so as to expose at least a portion of the first conductive portion 401 and at least a portion of the data line DL.

In the manufacturing process of the display substrate in FIG. 24, the first buffer layer BFL1 does not need to be etched separately, but the first via hole V1 may be formed at the same time when the fifth via hole V5 is formed, so that the manufacturing process may be simplified.

Similarly to FIGS. 19 to 20, in FIGS. 22 to 24, the active layer 400 may have a line-shaped structure or an L-shaped structure, which may refer to the above description and is not described herein again.

In FIGS. 22 to 24, the active layer 400 may include only the second sub-layer 40a2, or may adopt the double-layer structure in FIG. 4, or may adopt a triple-layer structure in FIG. 9.

Other structures of the display substrate shown in FIGS. 22 to 24 may refer to the arrangement in FIG. 21, and are not repeated herein.

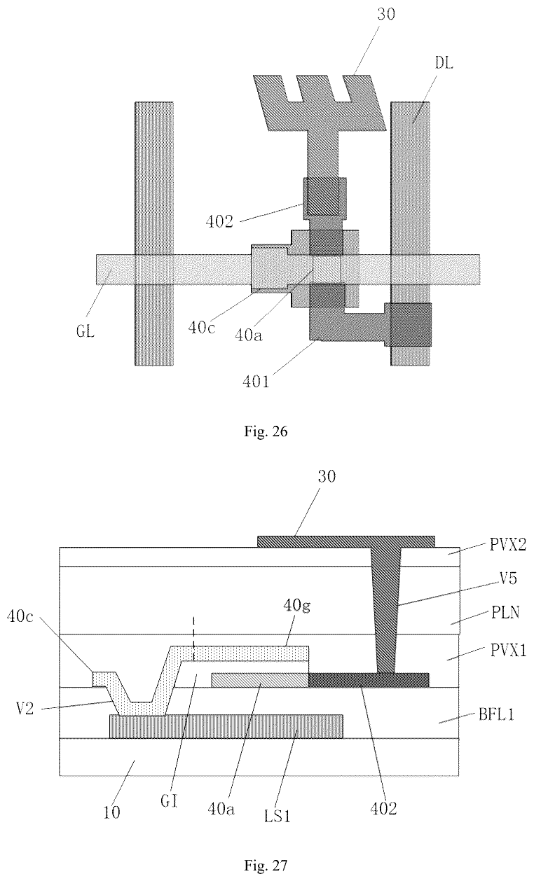

FIG. 25 is a schematic diagram showing a connection between a thin film transistor and a data line, a gate line, and a pixel electrode in a third embodiment of the present disclosure, FIG. 26 is schematic diagram showing a connection between the thin film transistor and the data line, the gate line, and the pixel electrode in the third embodiment of the present disclosure, and FIG. 27 is a cross-sectional view of the structure in FIG. 25 taken along a line G-G′. The display substrate shown in FIGS. 25 to 27 is different from that shown in FIG. 21 in that: the thin film transistor 40 shown in FIGS. 25 to 27 further includes a gate connection portion 40c, where the gate connection portion 40c and the gate 40g are connected into an integral structure (a single piece). The gate connection part 40c is electrically connected to the first light-shielding layer LS1 through a second via hole V2 penetrating through the first buffer layer BFL1.

In an example, as shown in FIG. 25, the gate 40g and the gate connection portion 40c are respectively located at two sides of the gate line GL in a width direction of the gate line GL, the gate 40g is located on a side of the gate line GL close to the active layer 400, and the gate connection portion 40c is located on a side of the gate line GL away from the active layer 400. The gate 40g, the gate connection portion 40c, and the gate line GL are connected into an integral structure; the active layer 400 has a line-shaped structure.

In another example, the gate connection portion 40c and the gate 40g are arranged in a first direction, and the active layer 400 has an L-shaped structure. For example, as shown in FIG. 26, the gate connection portion 40c and the gate 40g are arranged along a direction in which the gate line GL extends. Certainly, in FIG. 26, the gate connection portion 40c and the gate 40g may be arranged in other ways, for example, the gate 40g is a part of the gate line GL, and the gate connection portion 40c is located on a side of the gate line GL in the width direction of the gate line.

In FIGS. 25 to 27, the active layer 400 may have a single-layer structure, or the double-layer structure in FIG. 4, or the triple-layer structure in FIG. 9.

Other structures of the display substrate shown in FIGS. 25 to 27 may refer to the arrangement in FIG. 21, and are not repeated herein.

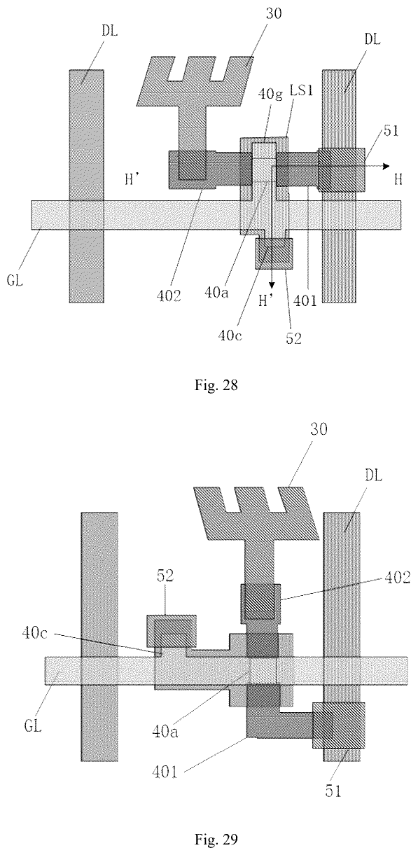

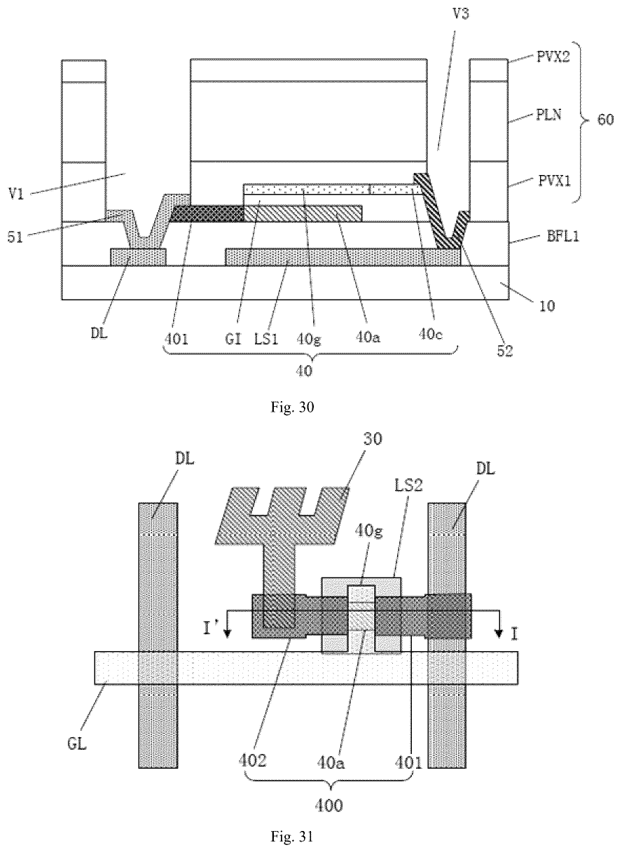

FIG. 28 is a schematic diagram showing a connection between a thin film transistor and a data line, a gate line, and a pixel electrode in a fourth embodiment of the present disclosure, FIG. 29 is another schematic diagram showing a connection between the thin film transistor and the data line, the gate line, and the pixel electrode in the fourth embodiment of the present disclosure, and FIG. 30 is a cross-sectional view of the structure in FIG. 28 taken along a line H-H′.

The display substrate shown in FIGS. 28 to 30 is similar to that shown in FIG. 23, except that the display substrate in FIGS. 28 to 30 further includes a second transfer electrode 52, where the second transfer electrode 52 is disposed in the same layer as the pixel electrode 30, and electrically connects the gate connection portion 40c to the first light-shielding layer LS1 through a third via hole V3. The third via hole V3 penetrates through the first passivation layer PVX1, the second passivation layer PVX2 and the planarization layer PLN, and exposes at least a portion of the gate connection portion 40c and at least a portion of the first light-shielding layer LS1.

The second transfer electrode 52 may be entirely located in the third via hole V3, or a part of the second transfer electrode may be located in the third via hole V3, and another part of the second transfer electrode overlaps a surface of the second passivation layer PVX2 away from the base substrate 10.

In the manufacturing process of the display substrate in FIGS. 28 to 30, the first buffer layer BFL1 does not need to be etched separately, and the third via hole V3 may be formed at the same time when the fifth via hole V5 is formed, so that the manufacturing process may be simplified.

For example, in FIG. 28, the gate connection portion 40c and the gate 40g may be respectively located at opposite sides of the gate line GL, and the active layer 400 has a line-shaped structure. In FIG. 29, the active layer 400 has an L-shaped structure, the gate 40g is a part of the gate line GL, and the gate connection portion 40c is located on a side of the gate line GL in a width direction of the gate line GL.

In FIGS. 28 to 30, the active layer 400 may have the single-layer structure, or the double-layer structure in FIG. 4, or the triple-layer structure in FIG. 9.

Other structures of the display substrate shown in FIGS. 28 to 30 may refer to the arrangement in FIG. 21, and are not repeated herein.

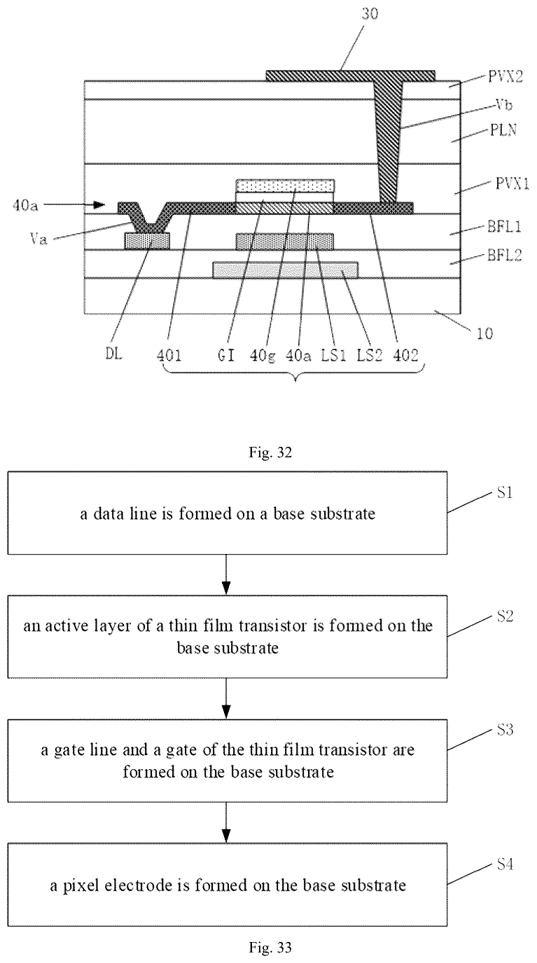

FIG. 31 is a schematic diagram showing a connection between a thin film transistor and a data line, a gate line, and a pixel electrode in a fifth embodiment of the present disclosure, and FIG. 32 is a cross-sectional view of the structure in FIG. 31 taken along a line I-I′.

The display substrate shown in FIGS. 31 to 32 is similar to that in FIG. 21, except that the thin film transistor 40 in FIGS. 31 to 32 further includes a second light-shielding layer LS2, the second light-shielding layer LS2 is located between the first light-shielding layer LS1 and the base substrate 10, and a second buffer layer BFL2 is provided between the first light-shielding layer LS1 and the second light-shielding layer LS2.

In FIGS. 31 to 32, an overlapping area of the first light-shielding layer LS1 and the channel portion 40a is less than or equal to an area of an orthographic area of the channel portion 40a on the base substrate 10. The overlapping area of the first light-shielding layer LS1 and the channel portion 40a is an area of an overlapping region of an orthographic projection of the first light-shielding layer LS1 on the base substrate 10 and the orthographic projection of the channel portion 40a on the base substrate 10. An orthographic projection of the second light-shielding layer LS2 on the base substrate 10 covers and exceeds the orthographic projection of the channel portion 40a on the base substrate 10.

In the embodiment illustrated in FIGS. 31 to 32, the overlapping area of the first light-shielding layer LS1 and the channel portion 40a is small, so that a magnitude of a parasitic capacitance formed by the first light-shielding layer LS1 and the channel portion 40a can be reduced. In addition, an area of the orthographic projection of the second light-shielding layer LS2 on the base substrate 10 is large, so that the channel portion 40a is ensured not to be irradiated with light.

In an example, the orthographic projection of the second light-shielding layer LS2 on the base substrate 10 may cover and exceed the orthographic projection of the gate 40g on the base substrate 10. For example, the orthographic projections of the gate 40g and the second light-shielding layer LS2 on the base substrate 10 are both rectangular, and there is an interval of at least 4 μm between each side of the orthographic projection of the gate 40g and a side, which is adjacent to the side of the orthographic projection of the gate 40g, of the orthographic projection of the second light-shielding layer LS2.

In the display substrate shown in FIGS. 31 to 32, the active layer 400 may have a single-layer structure, or the double-layer structure shown in FIG. 4, or the triple-layer structure shown in FIG. 9.

It should be noted that the above embodiments may be combined with each other, for example, for the display substrate in the third embodiment, the second light-shielding layer LS2 may be added. The first light-shielding layer LS1 and the second light-shielding layer LS2 may be provided as in the fifth embodiment.

An embodiment of the present disclosure further provides a method for manufacturing a display substrate, FIG. 33 is a flowchart of a method for manufacturing a display substrate according to an embodiment of the present disclosure, and as shown in FIG. 33, the method for manufacturing the display substrate includes steps S1 to S4.

At step S1, a data line is formed on a base substrate.

At step S2, an active layer of a thin film transistor is formed on the base substrate.

At step S3, a gate line and a gate of the thin film transistor are formed on the base substrate, where the gate is electrically connected with the gate line.

At step S4, a pixel electrode is formed on the base substrate.

The active layer includes: a first conductive portion, a second conductive portion and a channel portion connected between the first conductive portion and the second conductive portion, where the channel portion and the gate are arranged opposite to each other and are insulated from each other, the gate is connected with the gate line, the first conductive portion is electrically connected with the data line, and the second conductive portion is electrically connected with the pixel electrode. A material of the active layer includes a metal oxide MxNyOz, where M and N respectively include any one or more of zinc, indium, gallium, tin and lanthanide metals, O is oxygen, x, y and z are natural numbers greater than 0, and 0.8≤x+y+≤1.0.

The method for manufacturing the display substrate will be described below with reference to various embodiments.

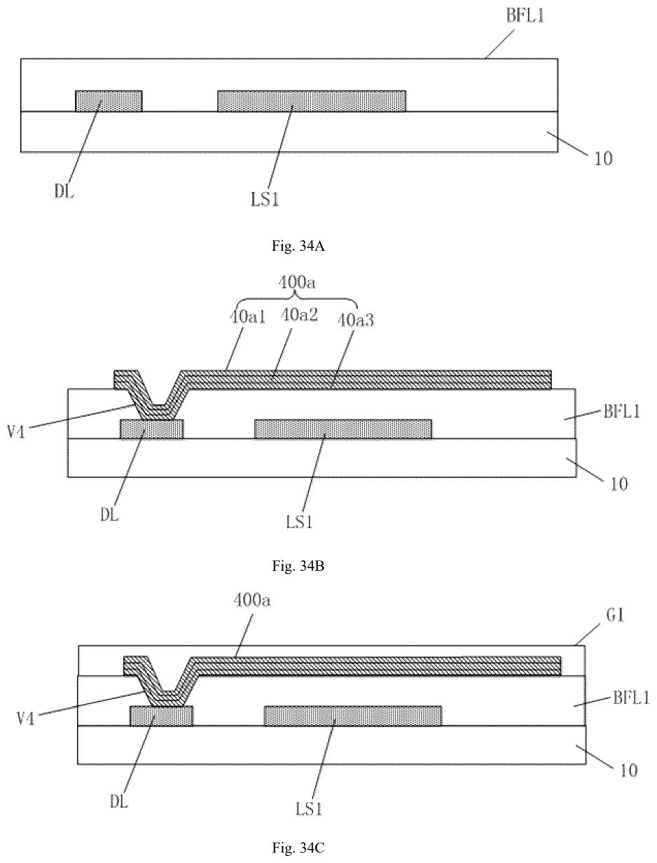

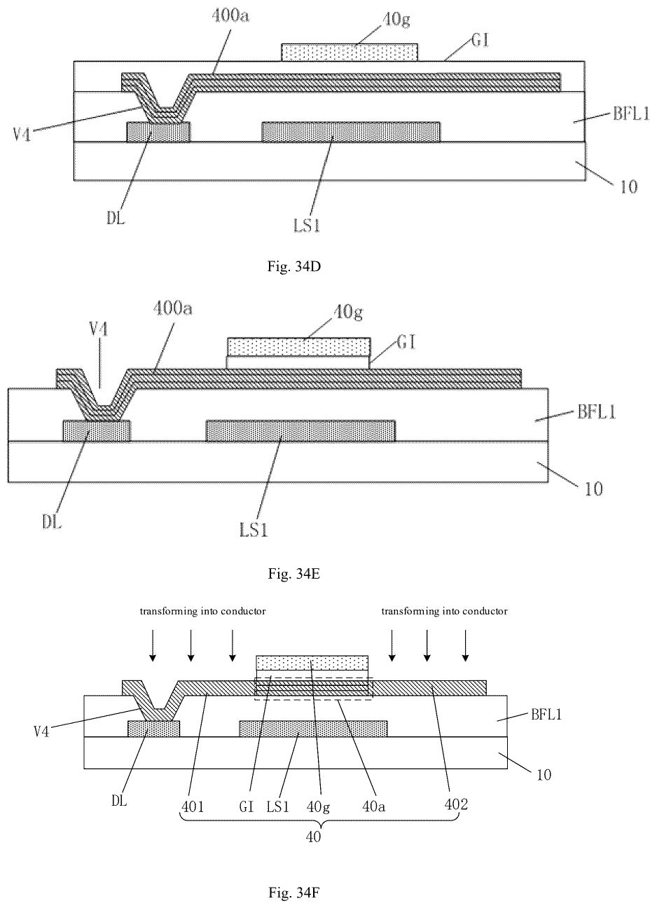

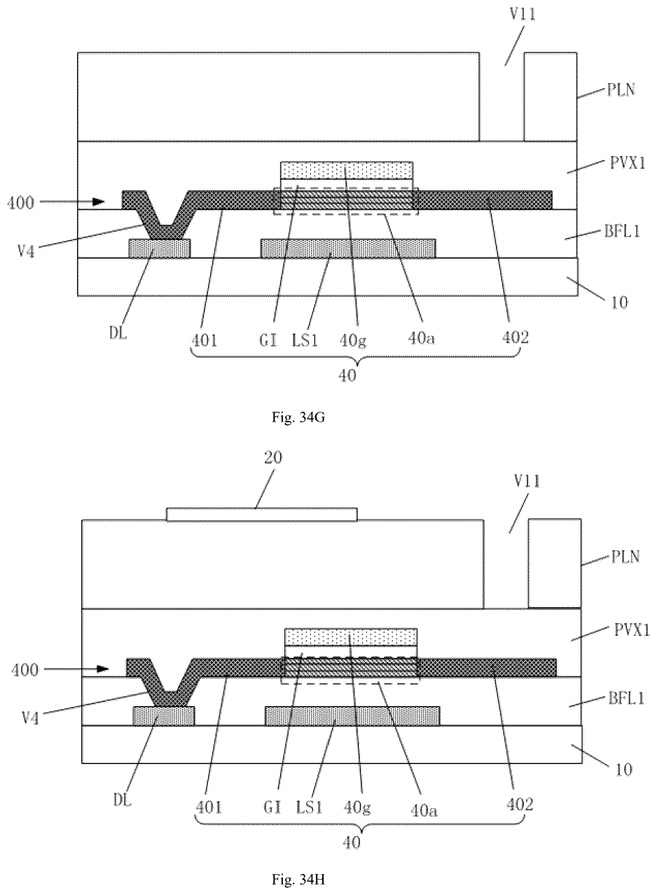

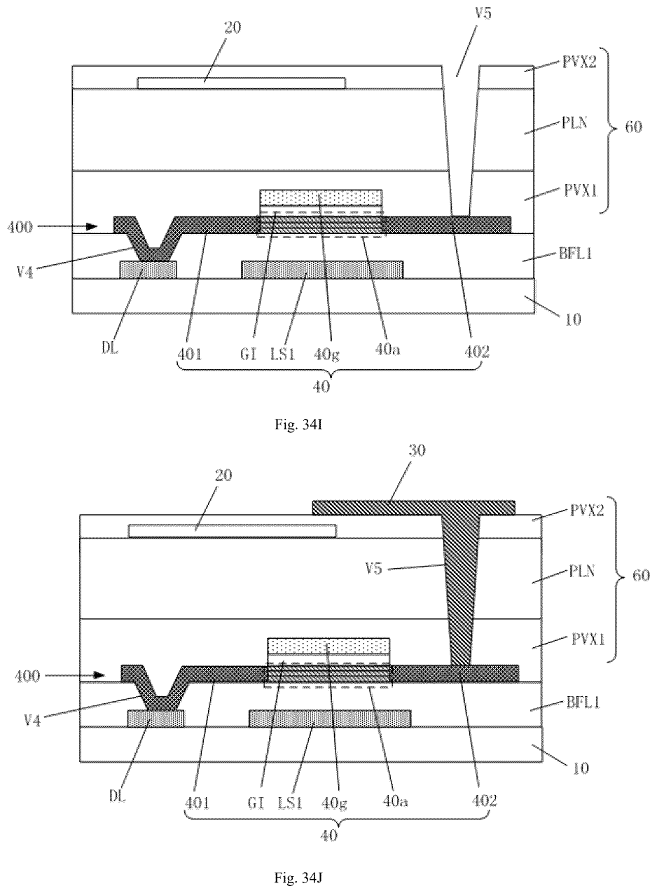

FIG. 34A to 34J are schematic diagrams illustrating a first method for manufacturing a display substrate, and the method in FIGS. 34A to 34J is used for manufacturing the display substrate according to the first embodiment.

As shown in FIGS. 34A to 34J, the method for manufacturing the display substrate includes steps S101 to S111.

At step S101, as shown in FIG. 34A, a data line DL and a first light-shielding layer LS1 are formed on the base substrate 10 in synchronization.

The step of forming the data line DL and the first light-shielding layer LS1 includes: forming a light-shielding metal layer and then performing a patterning process on the light-shielding metal layer, thereby forming the data line DL and the first light-shielding layer LS1. The light-shielding metal layer may include a first conductive material layer and a second conductive material layer, which are stacked, where the first conductive material layer is located on a side of the second conductive material layer away from the base substrate 10, and chemical activity of the first conductive material layer is less than chemical activity of the second conductive material layer. The first conductive material layer may include an alloy material, for example, an alloy of Mo, Ti, Nb. The second conductive material layer may include a metal material of copper.

Certainly, in other examples, the light-shielding metal layer may include a third conductive material layer in addition to the first conductive material layer and the second conductive material layer. The third conductive material layer is located on a side of the second conductive material layer close to the base substrate 10.

At step S102, as shown in FIG. 34A, a first buffer layer BFL1 is formed. In an example, the first buffer layer BFL1 may be formed using a chemical vapor deposition process. The specific material of the first buffer layer BFL1 may refer to the above description, and is not described again here.

At step S103, as shown in FIG. 34B, a fourth via hole V4 penetrating through the first buffer layer BFL1 is formed, and the fourth via hole V4 exposes a portion of the data line DL.

In some implementations, in step S103, the fourth via hole V4 may be formed through a photolithography patterning process.

At step S104, as shown in FIG. 34B, a semiconductor intermediate pattern 400a is formed. Specifically, a semiconductor material layer may be formed, and then, a photolithography patterning process may be performed on the semiconductor material layer to form the semiconductor intermediate pattern 400a. The semiconductor intermediate pattern 400a is electrically connected to the data line DL through the fourth via hole V4. The semiconductor intermediate pattern 400a includes a first sub-layer 40a1, a second sub-layer 40a2, and a third sub-layer 40a3, which are arranged along a direction close to the base substrate 10. The first sub-layer 40a1 and the third sub-layer 40a3 both include IGZO, and the second sub-layer 40a2 includes IGZTO.

In a preferred implementation, in each of first sub-layer 40a1 and third sub-layer 40a3, a molar ratio of the indium element, the gallium element and the zinc element is as follows: In:Ga:Zn=1:1:1. In the second sub-layer 40a2, the molar ratio of the indium element, the gallium element, the zinc element and the tin element is as follows: In:Ga:Zn:Sn=3.8:1.2:4:1.

At step S105, as shown in FIG. 34C, a gate insulating layer GI is formed. In an example, the gate insulating layer GI may be formed by using a chemical vapor deposition process. A specific material of the gate insulating layer GI may refer to the above description, and is not described again herein.

At step S106, as shown in FIG. 34D, a gate 40g of the thin film transistor 40 and a gate line GL are formed.

In the step S106, the gate 40g and the gate line GL may be formed by using a photolithography patterning process. The gate 40g of the thin film transistor 40 and the gate line GL corresponding thereto are formed as an integral structure (that is, gate 40g of the thin film transistor 40 and the gate line GL are formed into a single piece).

At step S107, as shown in FIG. 34E, the gate insulating layer GI is etched by using a gate metal layer as a mask. An orthographic projection of the etched gate insulating layer GI on the base substrate 10 coincides with or substantially coincides with an orthographic projection of the gate metal layer on the base substrate 10.

The gate metal layer is a pattern layer formed by the gate 40g, the gate line GL and other structures disposed in the same layer as the gate 40g and the gate line GL.

At step S108, as shown in FIG. 34F, a semiconductor intermediate pattern 400a is transformed into a conductor by using the gate metal layer as a mask, thereby forming an active layer 400 including a first conductive portion 401, a second conductive portion 402, and a channel portion 40a.

At step S109, as shown in FIG. 34G, a first passivation layer PVX1 and a planarization layer PLN are sequentially formed, and a first intermediate via hole is formed in the planarization layer PLN. The first intermediate via hole corresponds to the second conductive portion 402 in position.

In the step S109, the planarization layer PLN may be made of an organic material, and the first intermediate via hole may be formed by exposure and development.

At step S110, as shown in FIG. 34H, a common electrode 20 is formed.

The common electrode 20 may be formed by using a photolithography patterning process.

At step S111, as shown in FIG. 34I, a second passivation layer PVX2 is formed, and the second passivation layer PVX2 and the first passivation layer PVX1 are etched, thereby forming a fifth via hole V5, which penetrates through the first passivation layer PVX1, the second passivation layer PVX2 and the planarization layer PLN.

At step S112, as shown in FIG. 34J, a pixel electrode 30 is formed, and the pixel electrode 30 is electrically connected to the second conductive portion 402 through the fifth via hole V5.

The pixel electrode 30 may be formed by using a photolithography patterning process.

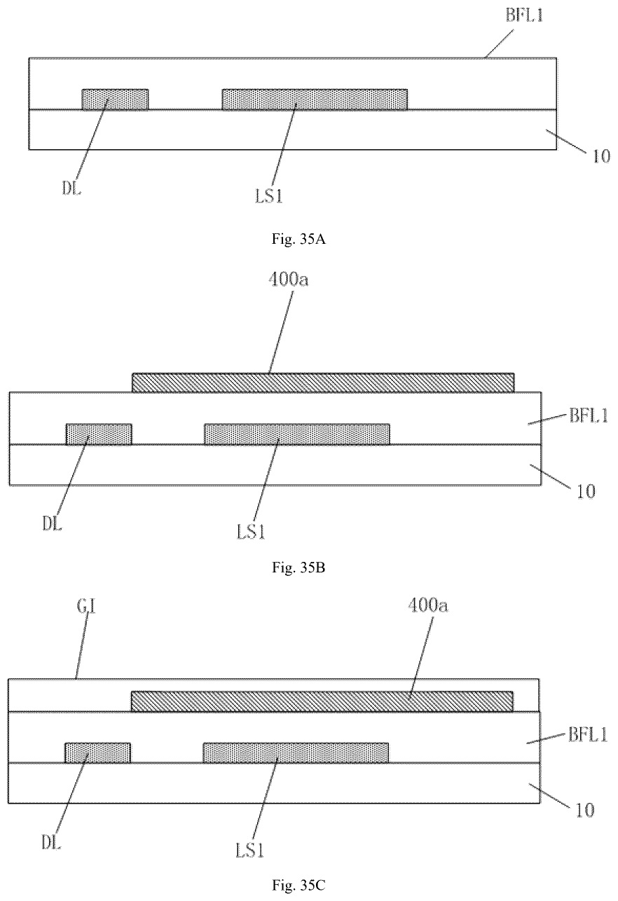

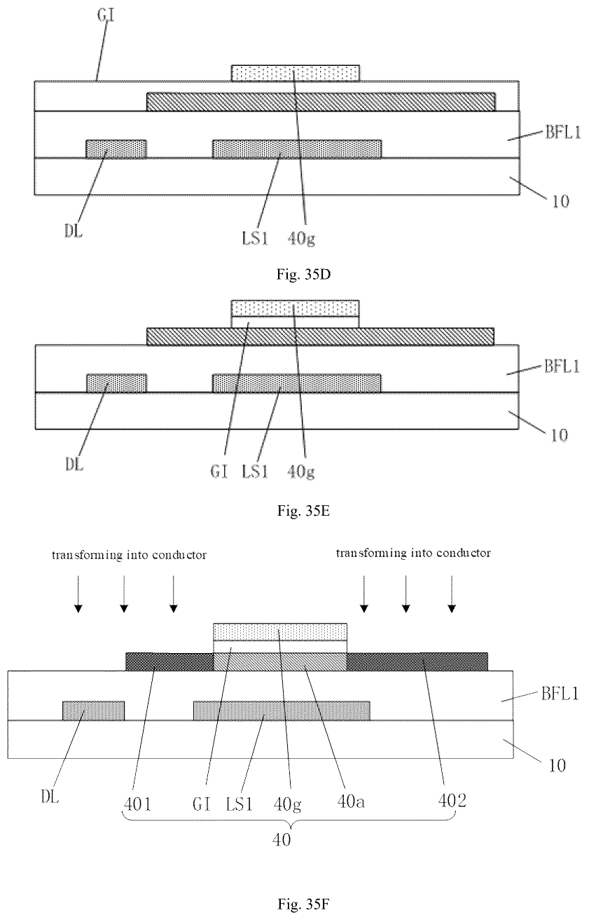

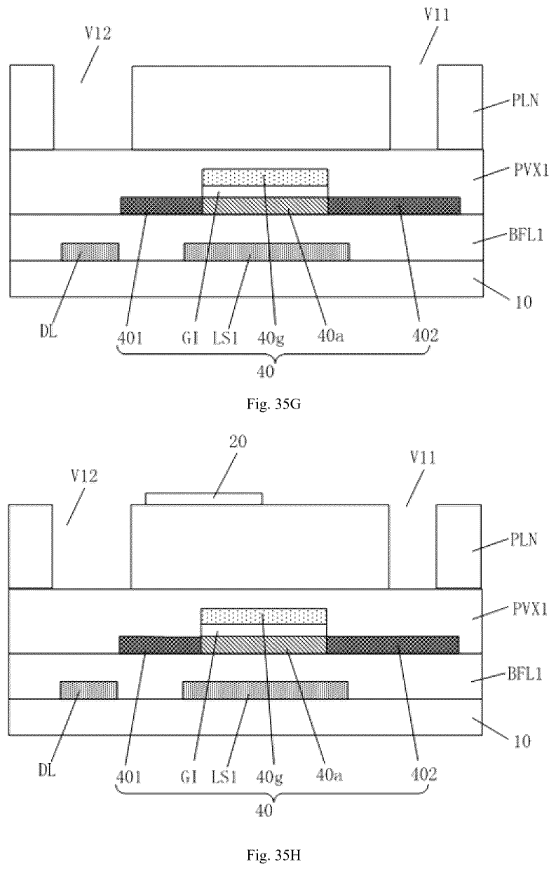

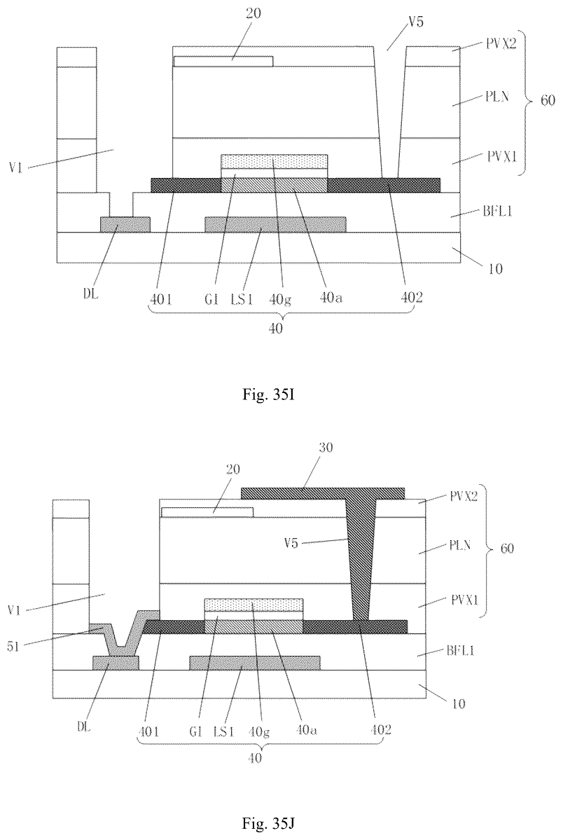

FIGS. 35A to 35J are schematic diagrams illustrating a second method for manufacturing a display substrate, and the method of FIG. 35A to 35J is used for manufacturing the display substrate of the second embodiment.

As shown in FIGS. 35A to 35J, the method for manufacturing the display substrate includes steps S201 to S211.

At step S201, as shown in FIG. 35A, a data line DL and a first light-shielding layer LS1 are formed on a base substrate 10 in synchronization. The step S201 is the same as the step S101, and is not described again herein.

At step S202, as shown in FIG. 35A, a first buffer layer BFL1 is formed. The step S202 is the same as the step S102, and is not described again herein.

At step S203, as shown in FIG. 35B, a semiconductor intermediate pattern 400a is formed. The step S203 is the same as the step S104, and is not described again herein.

At step S204, as shown in FIG. 35C, a gate insulating layer GI is formed. Step S204 is the same as step S105, and is not described herein again.

At step S205, as shown in FIG. 35D, a gate 40g of a thin film transistor 40 and a gate line GL are formed. The step S205 is the same as the step S106, and is not described again herein.

At step S206, as shown in FIG. 35E, the gate insulating layer GI is etched by using a gate metal layer as a mask. An orthographic projection of the etched gate insulating layer GI on the base substrate 10 coincides with or substantially coincides with an orthographic projection of the gate metal layer on the base substrate 10.

At step S207, as shown in FIG. 35F, the semiconductor intermediate pattern is transformed into a conductor by using the gate metal layer as a mask, thereby forming an active layer 400 including a first conductive portion 401, a second conductive portion 402, and a channel portion 40a.

At step S208, as shown in FIG. 35G, a first passivation layer PVX1 and a planarization layer PLN are sequentially formed, and a first intermediate via hole and a second intermediate via hole are formed in the planarization layer PLN. The first intermediate via hole V11 corresponds to the second conductive portion 402 in position, and the second intermediate via hole V12 corresponds to the data line DL and the first conductive portion 401 the position.

At step S209, as shown in FIG. 35H, a common electrode 20 is formed. The common electrode 20 may be formed by using a photolithography patterning process.

At step S210, as shown in FIG. 35I, a second passivation layer PVX2 is formed, and the is etched to form a fifth via hole V5 and a first via hole V1. The fifth via hole V5 penetrates through the first passivation layer PVX1, the second passivation layer PVX2 and the planarization layer PLN; the first via hole V1 penetrates through the first passivation layer PVX1, the second passivation layer PVX2, the planarization layer PLN, and the buffer layer. The first via hole VI exposes at least a portion of the first conductive portion 401 and a portion of the data line DL, and the fifth via hole V5 exposes at least a portion of the second conductive portion 402.

It is understood that, when the first via hole V1 is formed by etching, a part of the first buffer layer BFL1 that is blocked by the first conductive portion 401 is not etched due to the blocking effect of the first conductive portion 401.

At step S211, as shown in FIG. 35J, a pixel electrode 30 and a first transfer electrode 51 are formed in synchronization, the pixel electrode 30 is electrically connected to the second conductive portion 402 through the fifth via hole V5, and at least a part of the first transfer electrode 51 is located in the first via hole V1 and electrically connects the first conductive portion 401 to the data line DL.

The second method may reduce one patterning process compared to the first method, thereby simplifying the manufacturing process.

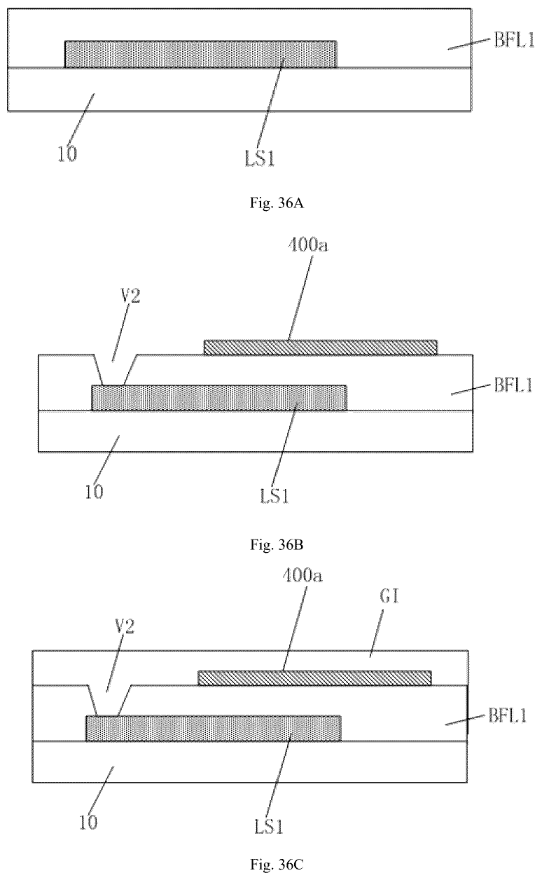

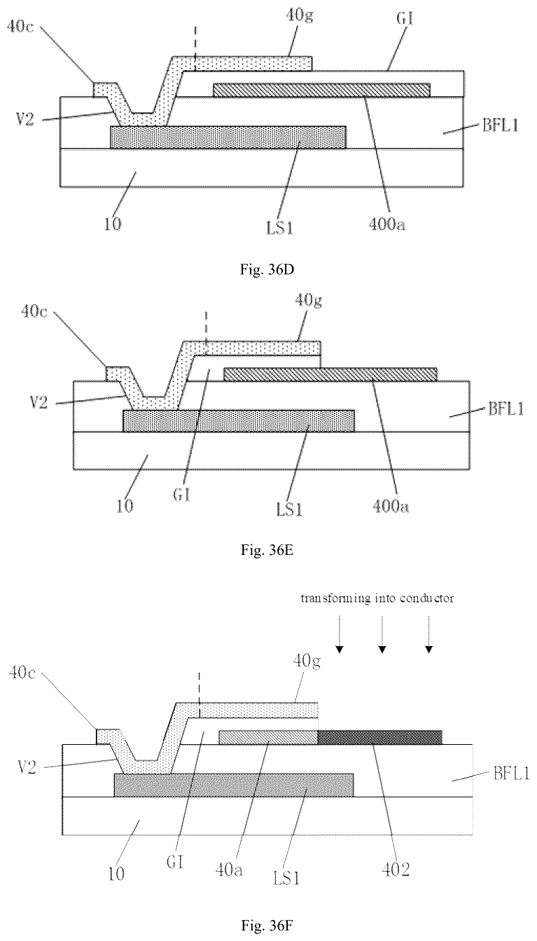

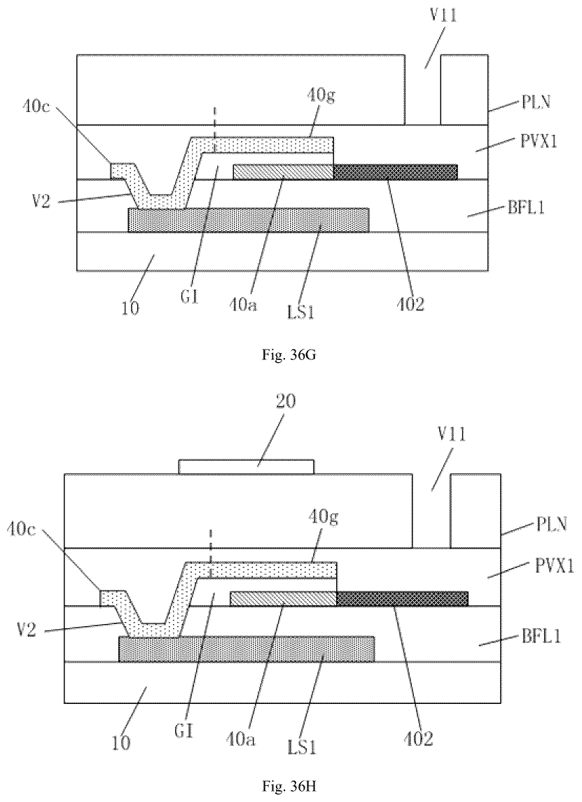

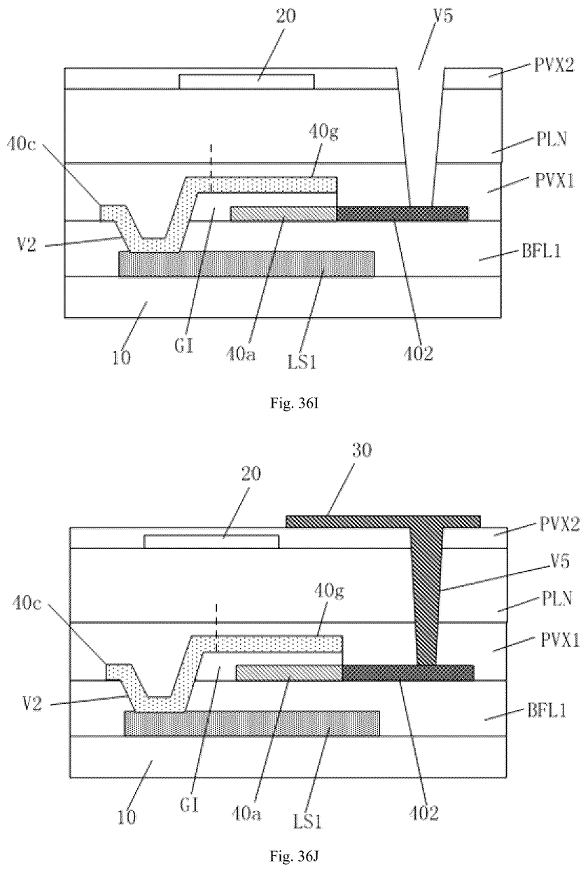

FIGS. 36A to 36J are schematic diagrams illustrating a third method for manufacturing a display substrate, and the method of FIGS. 36A to 36J is used for manufacturing the display substrate of the third embodiment. As shown in FIGS. 36A to 36J, the method for manufacturing the display substrate includes steps S301 to S308.

At step S301, as shown in FIG. 36A, a data line DL and a first light-shielding layer LS1 are formed on a base substrate 10 in synchronization. The step S301 is the same as the step S101, and is not described again herein.

At step S302, as shown in FIG. 36B, a first buffer layer BFL1 is formed. The step S202 is the same as the step S102, and is not described again herein.

At step S303, as shown in FIG. 36B, a fourth via hole V4 and a second via hole V2 penetrating through the first buffer layer BFL1 are formed, where the second via hole V2 exposes a part of the first light-shielding layer LS1. The fourth via hole V4 exposes a part of the data line DL, and specific positions of the fourth via hole V4 and the second via hole V2 may refer to FIG. 21.

At step S304, as shown in FIG. 36B, a semiconductor intermediate pattern 400a is formed. The step S304 is the same as the step S104, and is not described again herein.

At step S305, as shown in FIG. 36C, a gate insulating layer GI is formed. The step S305 is the same as the step S105, and is not described again herein.

At step S306, as shown in FIG. 36D, a gate 40g of the thin film transistor 40, a gate connection portion 40c, a gate line GL, and the like are formed. The gate 40g and the gate connection portion 40c and the gate line GL corresponding to the gate are connected to form an integral structure (a single piece). The gate connection portion 40c is electrically connected to the first light-shielding layer LS1 through the second via hole V2.

The step S306 is similar to the above-described step S106, except that the gate connection portion 40c is further formed in the step S306. The structures of the gate 40g and the active layer 400 may refer to FIGS. 25 to 27.

At step S307, as shown in FIG. 36E, the gate insulating layer GI is etched by using a gate metal layer as a mask. An orthographic projection of the etched gate insulating layer GI on the base substrate 10 coincides with or substantially coincides with an orthographic projection of the gate metal layer on the base substrate 10.

At step S308, as shown in FIG. 36F, the semiconductor intermediate pattern is transformed into a conductor by using the gate metal layer as a mask, thereby forming an active layer 400 including a first conductive portion 401, a second conductive portion 402, and a channel portion 40a. The positional relationship of the gate 40g and the active layer 400 may refer to FIGS. 25 to 27.

Then, the manufacturing process may be performed according to the steps S109 to S112, and the resulting structures are shown in FIGS. 36G to 36J.

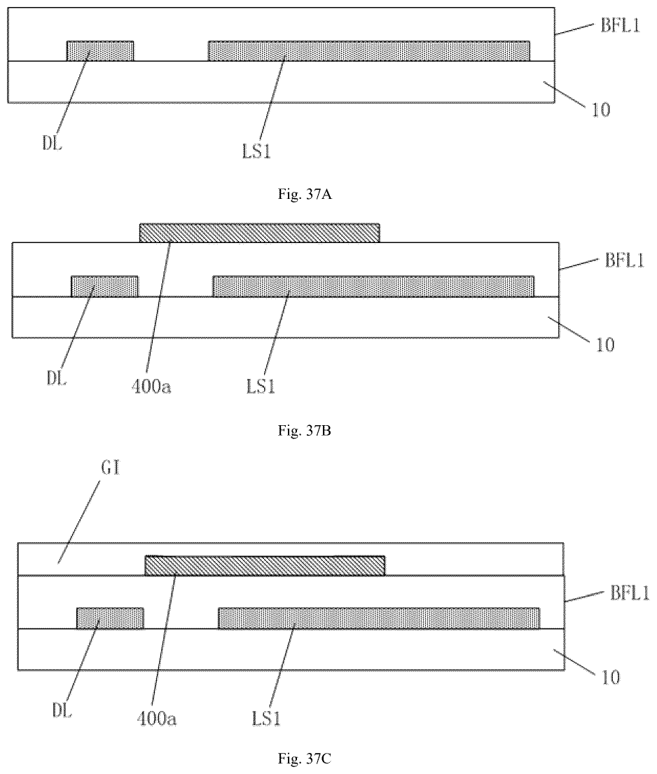

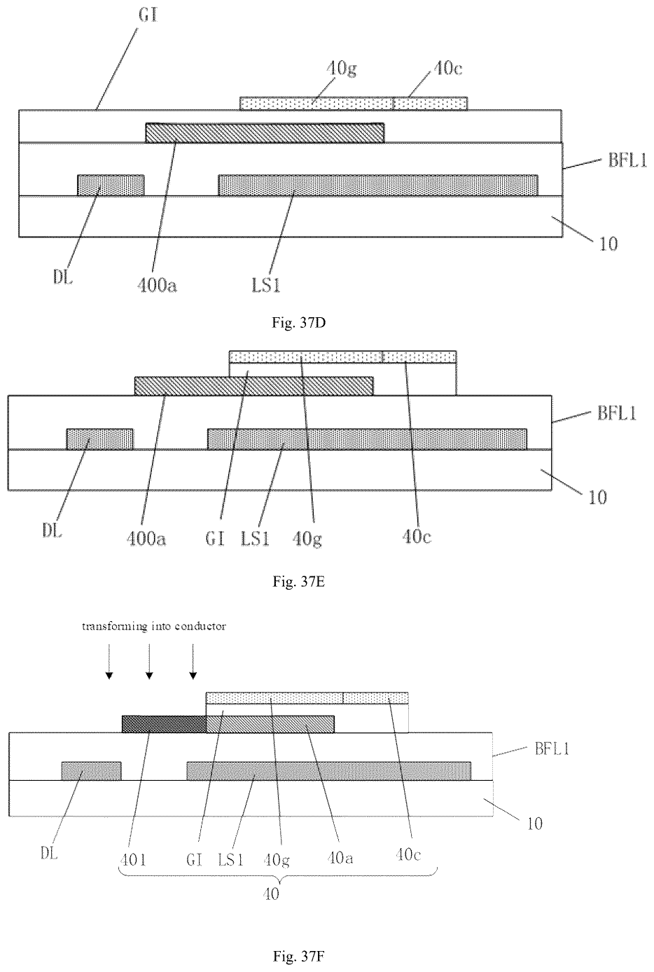

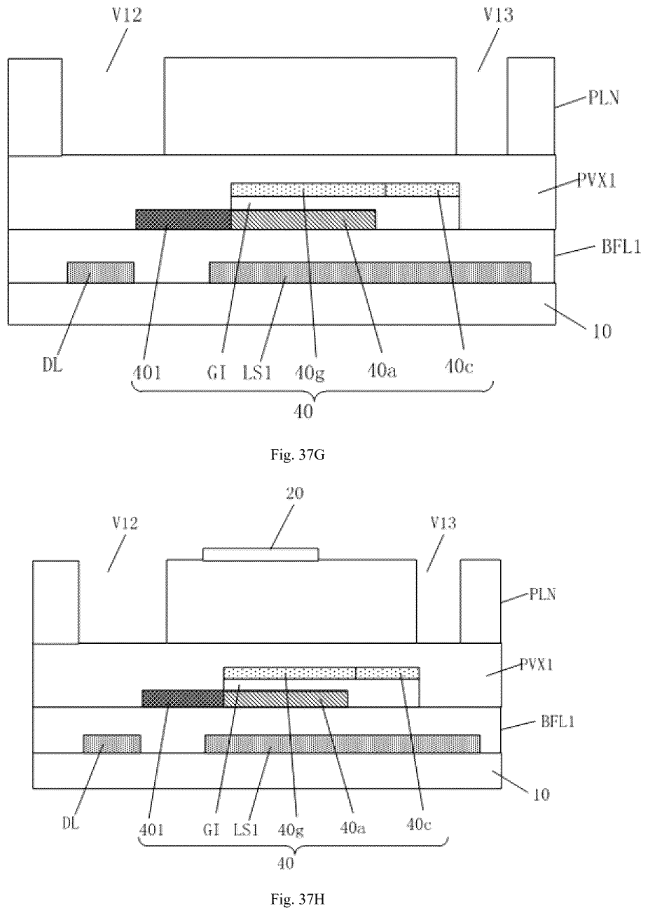

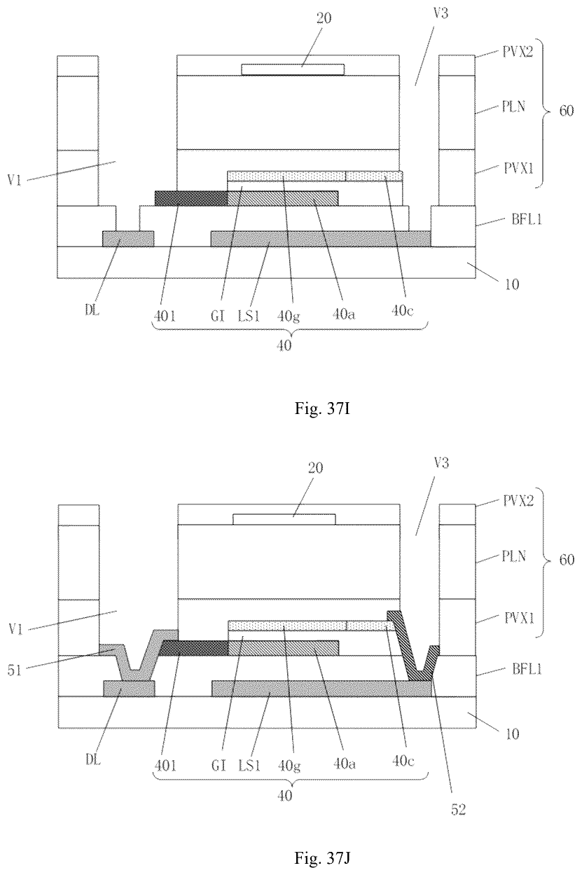

FIGS. 37A to 37J are schematic diagrams illustrating a fourth method for manufacturing a display substrate, and the method of FIG. 37A to 37J is used for manufacturing the display substrate of the fourth embodiment.

As shown in FIGS. 37A to 37J, the method for manufacturing the display substrate includes steps S401 to S411.

At step S401, as shown in FIG. 37A, a data line DL and a first light-shielding layer LS1 are formed on a base substrate 10 in synchronization. The step S401 is the same as the step S101, and is not described again herein.

At step S402, as shown in FIG. 37A, a first buffer layer BFL1 is formed. The step S402 is the same as the step S102, and is not described again herein.

At step S403, as shown in FIG. 37B, a semiconductor intermediate pattern 400a is formed. The step S203 is the same as the step S104, and is not described again herein.

At step S404, as shown in FIG. 37C, a gate insulating layer GI is formed. The step S404 is the same as the step S105, and is not described again herein.

At step S405, as shown in FIG. 37D, a gate 40g of a thin film transistor 40, a gate connection portion 40c, a gate line GL, and the like are formed. The gate 40g and the gate connection portion 40c and the gate line GL corresponding to the gate are connected as an integral structure (a single piece).

The step S405 is similar to the above-described step S106, except that the gate connection portion 40c is further formed in the step S405. The structures of the gate 40g and the active layer 400 may refer to the related figures of the fourth embodiment.

At step S406, as shown in FIG. 37E, the gate insulating layer GI is etched by using the gate metal layer as a mask. An orthographic projection of the etched gate insulating layer GI on the base substrate 10 coincides with or substantially coincides with an orthographic projection of the gate metal layer on the base substrate 10.

At step S407, as shown in FIG. 37F, the semiconductor intermediate pattern 400a is transformed into a conductor by using the gate metal layer as a mask, thereby forming an active layer 400 including the a conductive portion 401, a second conductive portion 402, and a channel portion 40a. The positional relationship between the gate 40g and the active layer 400 may refer to the related drawings of the fourth embodiment.

At step S408, as shown in FIG. 37G, a first passivation layer PVX1 and a planarization layer PLN are sequentially formed, and a first intermediate via hole, a second intermediate via hole, and a third intermediate via hole are formed in the planarization layer PLN. The first intermediate via hole corresponds to a position of the second conductive portion 402, the second intermediate via hole V12 corresponds to positions of the data line DL and the first conductive portion 401, and the third intermediate via hole V13 corresponds to positions of the gate connection portion 40c and the first light-shielding layer LS1.

At step S409, as shown in FIG. 37H, a common electrode 20 is formed.

At step S410, as shown in FIG. 37I, a second passivation layer PVX2 is formed, and the second passivation layer PVX2 and the first passivation layer PVX1 are etched, thereby forming a fifth via hole V5, a first via hole V1, and a third via hole V3, where the fifth via hole V5 penetrates through the first passivation layer PVX1, the second passivation layer PVX2, and the planarization layer PLN; the first via hole V1 and the third via hole V3 each penetrate through the first passivation layer PVX1, the second passivation layer PVX2, and the first buffer layer BFL1.

At step S411, as shown in FIG. 37J, a pixel electrode 30, a first transfer electrode 51, and a second transfer electrode 52 are formed in synchronization. The pixel electrode 30 is electrically connected to the second conductive portion 402 through the fifth via hole V5; at least a part of the first transfer electrode 51 is located in the first via hole V1 and electrically connects the first conductive portion 401 with the data line DL; at least a part of the second transfer electrode 52 is located in the third via hole V3, and electrically connects the gate connection portion 40c and the first light-shielding layer LS1.

Through the fourth method, it can form the thin film transistor 40 of the dual-gate structure, and can reduce one patterning process, compared to the first method, thereby simplifying the manufacturing process.

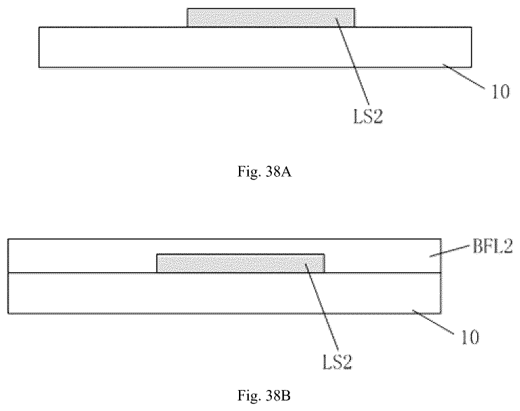

FIG. 38A to 38B are schematic diagrams illustrating a part of steps of a fifth method for manufacturing a display substrate, and the method of FIGS. 38A to 38B is used for manufacturing the display substrate of the fifth embodiment.

As shown in FIGS. 38A to 38B, the method for manufacturing a display substrate includes steps S501 to S502.

At step S501, as shown in FIG. 38A, a second light-shielding layer LS2 is formed on a base substrate 10. The second light-shielding layer LS2 is formed by using a photolithography patterning process.

At step S502, as shown in FIG. 38B, a second buffer layer BFL2 is formed.

Then, the display substrate may be manufactured according to the steps S101 to to S112. For the projections of the second light-shielding layer LS2 and the first light-shielding layer LS1, reference may be made to the description of the fifth embodiment, and details thereof are not repeated here.

The present disclosure further provides a display device, which includes any one of the display substrates in the above embodiments.

The display device may include any apparatus or product having a display function. For example, the display device may be a smart phone, a mobile phone, an e-book reader, a desktop computer (PC), a laptop PC, a netbook PC, a Personal Digital Assistant (PDA), a Portable Multimedia Player (PMP), a digital audio player, an ambulatory medical device, a camera, a wearable device (e.g., a head-mounted device, an electronic apparel, an electronic bracelet, an electronic necklace, an electronic accessory, an electronic tattoo, or a smart watch), a television, and so forth.

It will be understood that the above embodiments are merely exemplary embodiments employed to illustrate the principles of the present disclosure, and the present disclosure is not limited thereto. It will be apparent to those skilled in the art that various changes and modifications can be made therein without departing from the spirit and essence of the present disclosure, and these changes and modifications are to be considered within the scope of the present disclosure.

1. A thin film transistor, comprising a gate and an active layer disposed on a substrate base, wherein the active layer comprises: a first conductive portion, a second conductive portion, and a channel portion connected between the first conductive portion and the second conductive portion, the channel portion being opposite to the gate and insulated from the gate, a material of the active layer comprising a metal oxide MxNyOz, M and N respectively comprising any one or more of zinc, indium, gallium, tin, and lanthanide metals, O being an oxygen element, x, y, and z representing an molar ratio or mass fraction of M, N, O elements in the entire metal oxide, respectively, x, y, and z each being greater than 0, and 0.8≤x+y+z≤1.0.

2. The thin film transistor of claim 1, wherein the active layer is of a single-layer structure and comprises at least zinc, indium, gallium, tin and oxygen elements, a molar ratio of the indium element to the gallium element ranging from 3.6:1.2 to 4.0:1.2, a molar ratio of the gallium element to the zinc element ranging from 1:4 to 1.4:4, and a molar ratio of the zinc element to the tin element ranging from 3.8:1 to 4.2:1.

3. The thin film transistor of claim 1, wherein the active layer comprises a first sub-layer and a second sub-layer stacked in sequence, the first sub-layer is closer to the gate than the second sub-layer, and the second sub-layer has a hall mobility greater than that of the first sub-layer; the second sub-layer comprises at least zinc, indium, gallium, tin and oxygen elements, a molar ratio of the indium element to the gallium element ranges from 3.6:1.2 to 4.0:1.2, a molar ratio of the gallium element to the zinc element ranges from 1:4 to 1.4:4, and a molar ratio of the zinc element to the tin element ranges from 3.8:1 to 4.2:1; and
the first sub-layer comprises at least zinc, indium, gallium and oxygen elements, a molar ratio of the indium element to the gallium element ranges from 0.8:1 to 1.2:1, and at molar ratio of the gallium element to the zinc element ranges from 0.8:1 to 1.2:1.

4. The thin film transistor according to claim 1, wherein the gate is located on a side of the active layer away from the base substrate, and the thin film transistor further comprises:
a first light-shielding layer located between the active layer and the base substrate, an orthographic projection of the first light-shielding layer on the base substrate is overlapped with an orthographic projection of the channel portion on the base substrate, and the first light-shielding layer is electrically connected with the gate.

5. The thin film transistor of claim 4, wherein the orthographic projection of the first light-shielding layer on the base substrate covers and exceeds the orthographic projection of the channel portion on the base substrate.

6. The thin film transistor of claim 4, wherein an overlapping area of the first light-shielding layer and the channel portion is less than or equal to an area of the orthographic of the channel portion on the base substrate; and
the thin film transistor further comprises:
a second light-shielding layer located between the first light-shielding layer and the base substrate, and an orthographic projection of the second light-shielding layer on the base substrate covers and exceeds the orthographic projection of the channel part on the base substrate.

7. The thin film transistor of claim 4, wherein the first light-shielding layer comprises: a first conductive layer, a second conductive layer and a third conductive layer which are sequentially stacked along a direction close to the base substrate, the first conductive layer being located on a side, away from the base substrate, of the second conductive layer, and a chemical activity of the first conductive layer being lower than that of the second conductive layer; an adhesive force of the third conductive layer to the base substrate being larger than an adhesive force of the second conductive layer to the base substrate.

8. The thin film transistor of claim 1, wherein the gate is located in a gate metal layer, a gate insulating layer is disposed between the gate and the active layer, and an orthographic projection of the gate insulating layer on the base substrate does not exceed an orthographic projection of the gate metal layer on the base substrate.

9. The thin film transistor of claim 1, wherein a width of the channel portion in a predetermined direction is equal to a width of the gate in the predetermined direction, the predetermined direction being a direction from the first conductive portion toward the second conductive portion.

10. A display substrate, comprising the thin film transistor of claim 1, wherein
the display substrate further comprises a gate line, a data line and a pixel electrode which are arranged on the base substrate, the gate of the thin film transistor is connected with the gate line, the first conductive portion is electrically connected with the data line, and the second conductive portion is electrically connected with the pixel electrode.

11. The display substrate of claim 10, wherein the active layer is located on a side of a layer where the data line is located away from the base substrate, the gate is located on a side of the active layer away from the base substrate, and the pixel electrode is located on a side of a layer where the gate is located away from the base substrate, and wherein
the display substrate further comprises:
a buffer layer located between the layer where the data line is located and a layer where the active layer is located;
an insulating spacing layer located between the layer where the gate is located and a layer where the pixel electrode is located; and
a first transfer electrode located in the same layer as the pixel electrode, and electrically connects the first conductive portion with the data line through a first via hole;
the first via hole penetrating through the buffer layer and the insulating spacing layer, and exposing at least part of the first conductive portion and at least part of the data line.

12. The display substrate of claim 10, wherein the thin film transistor further comprises:
a first light-shielding layer located in the same layer as the data line, wherein an orthographic projection of the first light-shielding layer on the base substrate is overlapped with an orthographic projection of the channel part on the base substrate.

13. The display substrate of claim 12, wherein the display substrate further comprises:
a gate connection portion connected with the gate as an integral structure, the gate connection portion being electrically connected with the first-shielding layer through a second via hole.

14. The display substrate of claim 13, wherein the gate connection portion is located on a side of the gate line away from the active layer; or,
the gate and the gate connection portion are arranged along a direction in which the gate line extends; or,
the gate is a portion of the gate line, and the gate connection portion is located at a side of the gate line in a width direction of the gate line.

15. The display substrate of claim 12, wherein the display substrate further comprises:
a gate connection portion connected with the gate as an integral structure;
a second transfer electrode located in the same layer as the pixel electrode and electrically connects the gate connection portion with the first-shielding layer through a third via hole;
the third via hole exposes at least a portion of the gate connection portion and at least a portion of the first light-shielding layer.

16. A method for manufacturing a display substrate, comprising:
forming a data line on a base substrate;
forming an active layer of a thin film transistor on the base substrate;
forming a gate line and a gate of the thin film transistor on the base substrate, the gate being electrically connected with the gate line;
forming a pixel electrode on the base substrate;
wherein, the active layer comprises: a first conductive portion, a second conductive portion and a channel part connected between the first conductive portion and the second conductive portion, the channel portion and the gate being oppositely arranged and insulated from each other, the gate being electrically connected with the gate line, the first conductive portion being electrically connected with the data line, and the second conductive portion being electrically connected with the pixel electrode; and a material of the active layer comprises a metal oxide MxNyOz, M and N respectively comprising any one or more of zinc, indium, gallium, tin and lanthanide metals, O being oxygen, x, y and z representing an molar ratio or mass fraction of M, N, O elements in the entire metal oxide, respectively, x, y, and z each being greater than 0, and 0.8≤x+y+z≤1.0.

17. The method of claim 16, wherein the active layer is formed after the data line is formed, the gate is formed after the active layer is formed, and the pixel electrode is formed after the gate is formed;
the method further comprises:
forming a buffer layer, the buffer layer being located between a layer where the data line is located and a layer where the active layer is located;
forming an insulating spacing layer, the insulating spacing layer being located between a layer where the gate is located and a layer where the pixel electrode is located;
forming a first via hole penetrating through the insulating spacing layer and the buffer layer, the first via hole exposing at least a portion of the first conductive portion and at least a portion of the data line; and
forming a first transfer electrode, the first transfer electrode electrically connecting the first conductive portion with the data line through the first via hole, wherein the first transfer electrode and the pixel electrode are formed in synchronization.

18. The method of claim 16, further comprising:
forming a first light-shielding layer while forming the data line, wherein, an orthographic projection of the first light-shielding layer on the base substrate is overlapped with an orthographic projection of the channel portion on the base substrate.

19. The method of claim 18, further comprising:
forming a gate connection portion, the gate connection and the gate being connected as an integral structure;
forming a third via hole, the third via hole penetrating through the buffer layer and the insulating spacing layer between the pixel electrode and the layer where the first-shielding layer is located, and exposing at least part of the gate connection portion and at least part of the first-shielding layer; and
forming a second transfer electrode while forming the pixel electrode, the second transfer electrode electrically connecting the gate connection portion with the first-shielding layer through the third via hole.

20. A display device, comprising the display substrate of claim 10.
